(19) United States
(12) Patent Application Publication
(10) Pub. No.: US 2021/0111348 A1
(43) Pub. Date: Apr. 15, 2021

(54) POLYMER FOR ORGANIC ELECTROLUMINESCENT ELEMENT AND ORGANIC ELECTROLUMINESCENT ELEMENT

(71) Applicant: NIPPON STEEL CHEMICAL & MATERIAL CO., LTD., Tokyo (JP)

(72) Inventors: Kentaro HAYASHI, Tokyo (JP); Takuo NAGAHAMA, Tokyo (JP); Yuji IKENAGA, Tokyo (JP)

(73) Assignee: Nippon Steel Chemical & Material Co., Ltd., Tokyo (JP)

(21) Appl. No.: 16/981,004

(22) PCT Filed: Mar. 8, 2019
(86) PCT No.: PCT/JP2019/009348

§ 371 Date: Sep. 15, 2020

(30) Foreign Application Priority Data
Mar. 23, 2018 (JP) 2018-056819

(51) Int. Cl. H01L 51/00; C08G 61/10; C09K 11/06

(52) U.S. Cl. CPC H01L 51/0043; C08G 61/10; H01L 51/5012; C09K 11/06; H01L 51/0035

(57) ABSTRACT

Provided is a polymer for an organic electroluminescent device, which has high luminous efficiency and high durability, and is applicable to a wet process. In an organic electroluminescent device having laminated, on a substrate, an anode, organic layers, and a cathode, a material containing the polymer for an organic electroluminescent device, which includes a polyphenylene main chain having a pentacyclic fused heterocyclic structure in a side chain thereof, is used in at least one layer of the organic layers.

### TECHNICAL FIELD

The present invention relates to a polymer for an organic electroluminescent device and an organic electroluminescent device (hereinafter referred to as “organic EL device”), and more specifically, to a material for an organic EL device using a polyphenylene having a specific fused aromatic heterocyclic structure.

### BACKGROUND ART

An organic EL device has been rapidly put into practical use in a field, such as a display or lighting, because the device has features in terms of structure and design, such as a small thickness, a light weight, and flexibility, in addition to features in terms of characteristics, such as high contrast, high-speed responsiveness, and a low power consumption. Meanwhile, the device still leaves room for improvement in terms of, for example, luminance, efficiency, lifetime, and cost, and hence various researches and developments on materials and device structures have been performed.

To exhibit the characteristics of the organic EL device to the fullest extent, a hole and an electron generated from its electrodes need to be recombined without any waste. To that end, there are generally used a plurality of functional thin films that are function-separated, such as an injecting layer, a transporting layer, and a blocking layer for each of a hole and an electron, a charge-generating layer configured to generate charge except the electrodes, and a light-emitting layer configured to efficiently convert an exciton produced by the recombination into light.

Processes for the formation of the functional thin films of the organic EL device are roughly classified into a dry process typified by a deposition method and a wet process typified by a spin coating method or an inkjet method. When those processes are compared to each other, it can be said that the wet process is suitable for improvements in terms of cost and productivity because the process has a high material utilization ratio and enables the formation of a thin film having high flatness on a substrate having a large area.

At the time of the formation of a material into a film by the wet process, a low-molecular weight material or a high-molecular weight material is used as the material. When the low-molecular weight material is used, there is a problem in that it is difficult to obtain a uniform and flat film owing to segregation or phase separation along with the crystallization of a low-molecular weight compound. Meanwhile, when the high-molecular weight material is used, the crystallization of the material is suppressed, and hence the uniformity of the film can be improved. However, the characteristics of the film are still insufficient, and hence further improvements of the characteristics have been required.

As an attempt to solve the problem, there have been reported a polymer material having incorporated thereinto, as a unit structure, an indolocarbazole structure showing high characteristics as a low-molecular weight material and a light-emitting device using the material. In, for example, each of Patent Literature 1 and Patent Literature 2, there is a disclosure of a polymer using an indolocarbazole structure as its main chain. In addition, in Patent Literature 3, there is a disclosure of a polymer having an indolocarbazole structure in a side chain thereof. However, the characteristics of a device using any one of the polymers, such as efficiency and durability, are insufficient, and hence further improvements of the characteristics have been required.

### CITATION LIST

### Patent Literature

[PTL 1] US 2004/0137271 A1

[PTL 2] JP 6031030 B2

[PTL 3] WO 2011/105204 A1

### SUMMARY OF INVENTION

The present invention has been made in view of the problems, and an object of the present invention is to provide a polymer for an organic electroluminescent device, which has high luminous efficiency and high durability, and is applicable to a wet process. Another object of the present invention is to provide an organic electroluminescent device using the polymer, which is used in, for example, a lighting apparatus, an image display apparatus, or a backlight for a display apparatus.

The inventors of the present invention have made extensive investigations, and as a result, have found that a polymer, which includes a polyphenylene structure in its main chain and includes a structure containing a specific fused aromatic heterocycle, is applicable to a wet process at the time of the production of an organic electroluminescent device, and improves the efficiency and lifetime characteristic of the light-emitting device. Thus, the inventors have completed the present invention.

The present invention relates to a polymer for an organic electroluminescent device, and relates to an organic electroluminescent device including a polyphenylene having a specific fused heterocyclic structure, and organic layers between an anode and a cathode laminated on a substrate, in which at least one layer of the organic layers is a layer containing the polymer.

That is, according to one embodiment of the present invention, there is provided a polymer for an organic electroluminescent device, including: a polyphenylene structure in a main chain thereof; and a structural unit represented by the following general formula (1) as a repeating unit, wherein the structural units each represented by the general formula (1) may be the same or different from repeating unit to repeating unit, and wherein the polymer has a weight-average molecular weight of 1,000 or more and 500,000 or less:

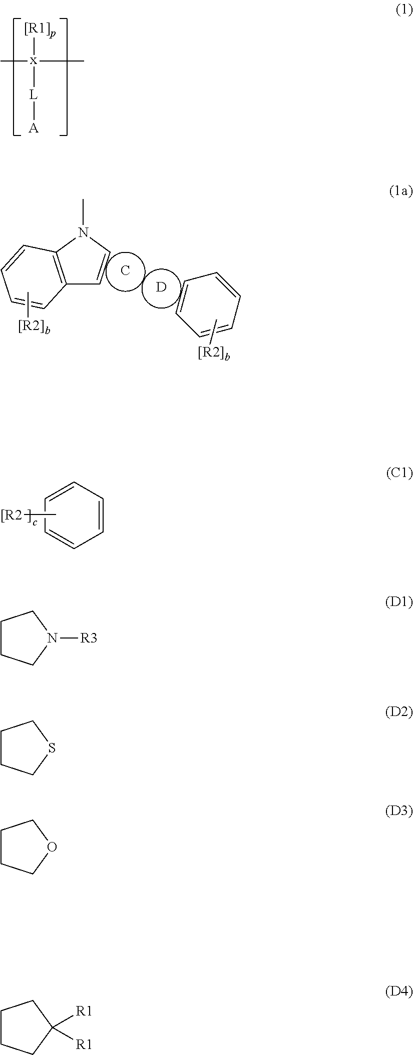

in the general formula (1),

“x” represents a phenylene group linked at an arbitrary position, or a linked phenylene group obtained by linking the 2 to 6 phenylene groups at arbitrary positions,

A represents a fused aromatic ring group represented by the formula (1a),

a ring C represents an aromatic ring represented by the formula (C1), which is fused with two adjacent rings at arbitrary positions,

a ring D represents a five-membered ring represented by the formula (D1), (D2), (D3), or (D4), which is fused with two adjacent rings at arbitrary positions,

L represents a single bond, a substituted or unsubstituted aromatic hydrocarbon group having 6 to 24 carbon atoms, a substituted or unsubstituted aromatic heterocyclic group having 3 to 21 carbon atoms, or a linked aromatic group obtained by linking a plurality of aromatic rings of the aromatic hydrocarbon group or the aromatic heterocyclic group,

R1, R2, and R3 each independently represent deuterium, a halogen, a cyano group, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, a dialkylamino group having 2 to 40 carbon atoms, a diarylamino group having 12 to 44 carbon atoms, a diaralkylamino group having 14 to 76 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 24 carbon atoms, a substituted or unsubstituted aromatic heterocyclic group having 3 to 21 carbon atoms, or a linked aromatic group obtained by linking a plurality of aromatic rings of the aromatic hydrocarbon group or the aromatic heterocyclic group, and when any one of the groups has a hydrogen atom, the hydrogen atom may be substituted with deuterium or a halogen, and

“b”, “c”, and “p” each represent a substitution number, “b”s each independently represent an integer of from 0 to 4, “c” represents an integer of from 0 to 2, and “p” represents an integer of from 0 to 3.

The polymer for an organic electroluminescent device according to the one embodiment of the present invention may be a polymer including a structural unit represented by the following general formula (2):

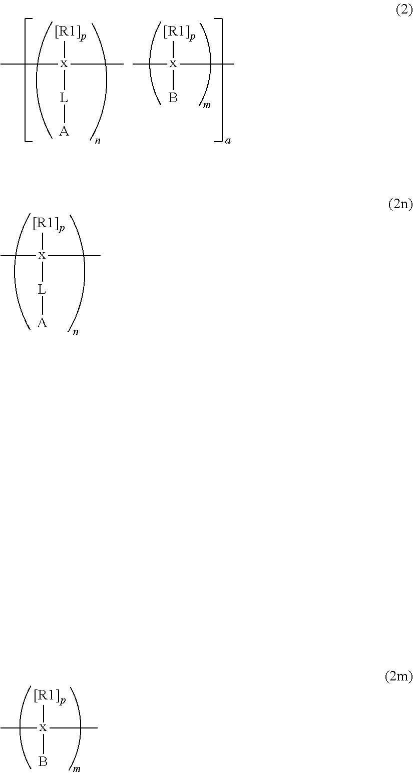

wherein the structural unit represented by the general formula (2) includes a structural unit represented by the formula (2n) and a structural unit represented by the formula (2m), the structural units each represented by the formula (2n) may be the same or different from repeating unit to repeating unit, and the structural units each represented by the formula (2m) may also be the same or different from repeating unit to repeating unit,

in the general formula (2), the formula (2n), and the formula (2m),

“x”, A, L, R1, and “p” are identical in meaning to those of the general formula (1),

B represents a hydrogen atom, a substituted or unsubstituted aromatic hydrocarbon group having 6 to 24 carbon atoms, a substituted or unsubstituted aromatic heterocyclic group having 3 to 17 carbon atoms, or a linked aromatic group obtained by linking a plurality of aromatic rings of the aromatic hydrocarbon group or the aromatic heterocyclic group,

“n” and “m” each represent an abundance molar ratio, and fall within ranges of 0.5≤n≤1 and 0≤m≤0.5, and

“a” represents an average number of the repeating units, and represents a number of from 2 to 1,000.

In the polymer for an organic electroluminescent device, the polyphenylene structure of the main chain is suitably linked at a meta position or an ortho position.

The polymer for an organic electroluminescent device suitably has a solubility in toluene at 40° C. of 0.5 wt % or more.

The polymer for an organic electroluminescent device suitably has a reactive group at a terminal, or in a side chain, of polyphenylene, and is suitably insolubilized through application of energy, such as heat or light.

According to one embodiment of the present invention, there is provided a composition for an organic electroluminescent device, including the soluble polymer for an organic electroluminescent device, which is dissolved or dispersed, alone or as a mixture with another material, in a solvent.

According to one embodiment of the present invention, there is provided a method of producing an organic electroluminescent device, including applying the composition for an organic electroluminescent device to form the composition into an organic layer.

According to one embodiment of the present invention, there is provided an organic electroluminescent device, including an organic layer containing the polymer for an organic electroluminescent device. The organic layer is at least one layer selected from a light-emitting layer, a hole-injecting layer, a hole-transporting layer, an electron-transporting layer, an electron-injecting layer, a hole-blocking layer, an electron-blocking layer, an exciton-blocking layer, and a charge-generating layer.

The polymer for an organic electroluminescent device according to the one embodiment of the present invention has the polyphenylene chain in its main chain, and has the fused heterocyclic structure in a side chain thereof. Accordingly, the polymer serves as a material for an organic electroluminescent device having a high charge-transporting characteristic, having high stability in an active state of oxidation, reduction, or excitation, and having high heat resistance. An organic electroluminescent device using an organic thin film formed from the polymer shows high luminous efficiency and high driving stability.

In addition, when, as a method of forming the polymer for an organic electroluminescent device according to the one embodiment of the present invention into a film, the polymer is mixed with the other material, and the mixture is vapor-deposited from one and the same deposition source, or the polymer and the material are simultaneously vapor-deposited from different deposition sources, a charge-transporting property in the organic layer, and a carrier balance between a hole and an electron therein are adjusted, and hence an organic EL device having higher performance can be achieved. Alternatively, when the polymer for an organic electroluminescent device according to the one embodiment of the present invention and the other material are dissolved or dispersed in one and the same solvent, and the resultant is used as the composition for an organic electroluminescent device in film formation, the charge-transporting property in the organic layer, and the carrier balance between a hole and an electron therein are adjusted, and hence an organic EL device having higher performance can be achieved.

### BRIEF DESCRIPTION OF DRAWINGS

FIG. 1 is a schematic sectional view for illustrating an example of an organic EL device.

FIG. 2 shows the phosphorescence spectrum of Example 1.

### DESCRIPTION OF EMBODIMENTS

A mode for carrying out the present invention is described in detail below.

A polymer for an organic electroluminescent device of the present invention includes: a polyphenylene structure in a main chain thereof; and a structural unit represented by the general formula (1) as a repeating unit, wherein the structural units each represented by the general formula (1) may be the same or different from repeating unit to repeating unit, and wherein the polymer has a weight-average molecular weight of 1,000 or more and 500,000 or less.

The polymer for an organic electroluminescent device of the present invention may include, as a repeating unit, a structural unit (2m) except a structural unit (2n) represented by the general formula (1) as represented by the general formula (2).

Herein, the structural units each represented by the formula (2n) may be the same or different from repeating unit to repeating unit, and the structural units each represented by the formula (2m) may also be the same or different from repeating unit to repeating unit.

“x” of the main chain represents a phenylene group bonded at an arbitrary position, or a linked phenylene group obtained by linking the 2 to 6 phenylene groups at arbitrary positions, preferably a phenylene group, or a linked phenylene group obtained by linking the 2 to 4 phenylene groups, more preferably a phenylene group, a biphenylene group, or a terphenylene group. Those groups may be each independently linked at an ortho position, a meta position, or a para position, and are each preferably linked at an ortho position or a meta position.

A represents a fused aromatic ring group represented by the formula (1a). A ring C represents an aromatic ring represented by the formula (C1), which is fused with two adjacent rings at arbitrary positions. A ring D represents a five-membered ring structure represented by any one of the formulae (D1), (D2), (D3), and (D4), which is fused with two adjacent rings at arbitrary positions.

A preferably represents an indolocarbazolyl group in which the ring D is represented by the formula (D1). The indolocarbazolyl group may come in six kinds of structural isomer groups because the group has a plurality of positions at which an indole ring and a carbazole ring can be fused with each other. Any one of the structural isomers is permitted.

L represents a single bond or a divalent group. The divalent group is a substituted or unsubstituted aromatic hydrocarbon group having 6 to 24 carbon atoms, a substituted or unsubstituted aromatic heterocyclic group having 3 to 18 carbon atoms, or a linked aromatic group obtained by linking a plurality of aromatic rings of the aromatic hydrocarbon group or the aromatic heterocyclic group. L preferably represents a single bond, a substituted or unsubstituted aromatic hydrocarbon group having 6 to 18 carbon atoms, a substituted or unsubstituted aromatic heterocyclic group having 3 to 15 carbon atoms, or a linked aromatic group obtained by linking 2 to 6 aromatic rings of the aromatic hydrocarbon group or the aromatic heterocyclic group. L more preferably represents a single bond, a substituted or unsubstituted aromatic hydrocarbon group having 6 to 12 carbon atoms, a substituted or unsubstituted aromatic heterocyclic group having 3 to 12 carbon atoms, or a linked aromatic group obtained by linking 2 to 4 aromatic rings of the aromatic hydrocarbon group or the aromatic heterocyclic group.

When such aromatic hydrocarbon group, aromatic heterocyclic group, or linked aromatic group has a substituent, the substituents are each independently, for example, the same group as that represented by R1 to be described later.

When L represents a linked aromatic group, the linked aromatic group is a group obtained through the linking of the aromatic rings of a substituted or unsubstituted aromatic hydrocarbon group, or a substituted or unsubstituted aromatic heterocyclic group by direct bonding, and the aromatic rings to be linked may be identical to or different from each other. In addition, when three or more aromatic rings are linked, the linked aromatic group may be linear or branched, and a bonding (hand) may be provided from a terminal aromatic ring, or may be provided from an intermediate aromatic ring. The linked aromatic group may have a substituent. The number of carbon atoms of the linked aromatic group is the total sum of carbon atoms that the substituted or unsubstituted aromatic hydrocarbon group, or the substituted or unsubstituted aromatic heterocyclic group for forming the linked aromatic group may have.

The linking of the aromatic rings (Ars) specifically refers to a group having such a structure as represented below.

Ar1-Ar2-Ar3-Ar4 (i)

Ar5-Ar6(Ar7)-Ar8 (ii)

In the formulae, Ar1 to Ar8 each represent an aromatic hydrocarbon group or an aromatic heterocyclic group (aromatic ring), and their respective aromatic rings are bonded to each other by direct bonding. Ar1 to Ar8 change independently of each other, and may each represent any one of an aromatic hydrocarbon group and an aromatic heterocyclic group. In addition, the linked aromatic group may be linear as represented by the formula (i), or may be branched as represented by the formula (ii). Each of the positions at which L is bonded to “x” and A in the formula (1) may be Ar1 or Ar4 serving as a terminal aromatic ring, or may be Ar3 or Ar6 serving as an intermediate aromatic ring.

When L represents an unsubstituted aromatic hydrocarbon group or an unsubstituted heterocyclic group, a specific example thereof is a group produced by removing a hydrogen atom from an aromatic compound, such as benzene, pentalene, indene, naphthalene, azulene, heptalene, octalene, indacene, acenaphthylene, phenalene, phenanthrene, anthracene, trindene, fluoranthene, acephenanthrylene, aceanthrylene, triphenylene, pyrene, chrysene, tetraphene, tetracene, pleiadene, picene, perylene, pentaphene, pentacene, tetraphenylene, cholanthrylene, a helicene, hexaphene, rubicene, coronene, trinaphthylene, heptaphene, pyranthrene, furan, benzofuran, isobenzofuran, xanthene, oxanthrene, dibenzofuran, peri-xanthenoxanthene, thiophene, thioxanthene, thianthrene, phenoxathiin, thionaphthene, isothianaphthene, thiophthene, thiophanthrene, dibenzothiophene, pyrrole, pyrazole, tellurazole, selenazole, thiazole, isothiazole, oxazole, furazan, pyridine, pyrazine, pyrimidine, pyridazine, triazine, indolizine, indole, indoloindole, indolocarbazole, isoindole, indazole, purine, quinolizine, isoquinoline, carbazole, imidazole, naphthyridine, phthalazine, quinazoline, benzodiazepine, quinoxaline, cinnoline, quinoline, pteridine, phenanthridine, acridine, perimidine, phenanthroline, phenazine, carboline, phenotellurazine, phenoselenazine, phenothiazine, phenoxazine, anthyridine, benzothiazole, benzimidazole, benzoxazole, benzisoxazole, or benzisothiazole. The group is preferably, for example, a group produced by removing a hydrogen atom from benzene, naphthalene, anthracene, triphenylene, pyrene, pyridine, pyrazine, pyrimidine, pyridazine, triazine, carbazole, indole, indoloindole, indolocarbazole, dibenzofuran, dibenzothiophene, quinoline, isoquinoline, quinoxaline, quinazoline, or naphthyridine. When L represents an unsubstituted linked aromatic group, the group is, for example, a group obtained through the bonding of two or more of those groups by direct bonding.

The aromatic hydrocarbon group, the aromatic heterocyclic group, or the linked aromatic group described above may have a substituent, and the substituent is preferably, for example, deuterium, a halogen, a cyano group, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, a dialkylamino group having 2 to 40 carbon atoms, a diarylamino group having 12 to 44 carbon atoms, a diaralkylamino group having 14 to 76 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, an aromatic hydrocarbon group having 6 to 24 carbon atoms, or an aromatic heterocyclic group having 3 to 18 carbon atoms. In addition, the same holds true for a substituent when the term “substituted aromatic hydrocarbon group”, “substituted aromatic heterocyclic group”, or “substituted linked aromatic group” is used in this description.

In this description, with regard to the number of carbon atoms when the range of the number of carbon atoms is defined in, for example, a substituted or unsubstituted aromatic hydrocarbon group, or a substituted or unsubstituted aromatic heterocyclic group, a substituent of any such group is excluded from the calculation of the number of carbon atoms. However, the number of carbon atoms including those of the substituent preferably falls within the range of the number of carbon atoms.

R1 represents deuterium, a halogen, a cyano group, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, a dialkylamino group having 2 to 40 carbon atoms, a diarylamino group having 12 to 44 carbon atoms, a diaralkylamino group having 14 to 76 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 24 carbon atoms, a substituted or unsubstituted aromatic heterocyclic group having 3 to 18 carbon atoms, or a linked aromatic group obtained by linking a plurality of aromatic rings of the aromatic hydrocarbon group or the aromatic heterocyclic group. When any one of the groups has a hydrogen atom, the hydrogen atom may be substituted with deuterium or a halogen, such as fluorine, chlorine, or bromine.

R1 preferably represents an alkyl group having 1 to 12 carbon atoms, an aralkyl group having 7 to 19 carbon atoms, an alkenyl group having 2 to 18 carbon atoms, an alkynyl group having 2 to 18 carbon atoms, a diarylamino group having 12 to 36 carbon atoms, a substituted or unsubstituted aromatic hydrocarbon group having 6 to 18 carbon atoms, a substituted or unsubstituted aromatic heterocyclic group having 3 to 15 carbon atoms, or a linked aromatic group obtained by linking 2 to 6 aromatic rings of the aromatic hydrocarbon group or the aromatic heterocyclic group. R1 more preferably represents an alkyl group having 1 to 8 carbon atoms, an aralkyl group having 7 to 15 carbon atoms, an alkenyl group having 2 to 16 carbon atoms, an alkynyl group having 2 to 16 carbon atoms, a diarylamino group having 12 to 32 carbon atoms, a substituted or unsubstituted aromatic hydrocarbon group having 6 to 16 carbon atoms, a substituted or unsubstituted aromatic heterocyclic group having 3 to 15 carbon atoms, or a linked aromatic group obtained by linking 2 to 4 aromatic rings of the aromatic hydrocarbon group or the aromatic heterocyclic group.

Specific examples thereof include, but not limited to: alkyl groups, such as methyl, ethyl, propyl, butyl, pentyl, hexyl, heptyl, octyl, nonyl, and decyl groups; aralkyl groups, such as benzyl, pyridylmethyl, phenylethyl, naphthomethyl, and naphthoethyl groups; alkenyl groups, such as vinyl, propenyl, butenyl, and styryl groups; alkynyl groups, such as ethynyl, propynyl, and butynyl groups; dialkylamino groups, such as dimethylamino, methylethylamino, diethylamino, and dipropylamino groups; diarylamino groups, such as diphenylamino, naphthylphenylamino, dinaphthylamino, dianthranylamino, and diphenanthrenylamino groups; diaralkylamino groups, such as dibenzylamino, benzylpyridylmethylamino, and diphenylethylamino groups; acyl groups, such as an acetyl group, a propanoyl group, a benzoyl group, an acryloyl group, and a methacryloyl group; acyloxy groups, such as an acetoxy group, a propanoyloxy group, a benzoyloxy group, an acryloyloxy group, and a methacryloyloxy group; alkoxy groups, such as a methoxy group, an ethoxy group, a propoxy group, a phenoxy group, and a naphthoxy group; alkoxycarbonyl groups, such as a methoxycarbonyl group, an ethoxycarbonyl group, a propoxycarbonyl group, a phenoxycarbonyl group, and a naphthoxycarbonyl group; alkoxycarbonyloxy groups, such as a methoxycarbonyloxy group, an ethoxycarbonyloxy group, a propoxycarbonyloxy group, a phenoxycarbonyloxy group, and a naphthoxycarbonyloxy group; alkylsulfonyl groups, such as a mesyl group, an ethylsulfonyl group, and a propylsulfonyl group; and the same aromatic hydrocarbon groups, aromatic heterocyclic groups, and linked aromatic groups as those described for L.

When X represents a linked phenylene group, R1 may substitute the same phenylene group as the phenylene group substituted with L, or may substitute any other phenylene group.

“p”, which represents a substitution number and represents an integer of from 0 to 3, preferably represents 0 or 1.

In the formula (1a), (C1), (D1), and (D4), R1, R2, and R3 are the same as R1 described above. However, R1, R2, and R3 may be each independently identical to or different from each other.

R3 preferably represents a substituted or unsubstituted aromatic hydrocarbon group having 6 to 24 carbon atoms, a substituted or unsubstituted aromatic heterocyclic group having 3 to 18 carbon atoms, or a linked aromatic group obtained by linking a plurality of aromatic rings of the aromatic hydrocarbon group or the aromatic heterocyclic group.

In the formulae (1a) and (C1), “b” and “c” each represent a substitution number, “b” represents an integer of from 0 to 4, and “c” represents an integer of from 0 to 2. It is preferred that “b” and “c” each represent 0 or 1.

In the soluble polymer for an organic electroluminescent device of the present invention, a substituent that reacts in response to an external stimulus, such as heat or light, may be added to a terminal or side chain of the polyphenylene structure, which is a main chain represented by the general formula (1) or (2), or to a group for forming R1, L, or A bonded to the main chain. The polymer having added thereto the reactive substituent may be insolubilized (its solubility in toluene at 40° C. may be less than 0.5 wt %) by a treatment, such as heating or exposure, after having been applied and formed into a film, and hence its application, lamination, film formation can be continuously performed. Although the reactive substituent is not limited as long as the substituent shows, for example, polymerization, condensation, crosslinking, or coupling reactivity through an external stimulus, such as heat or light, specific examples thereof include: a hydroxyl group; a carbonyl group; a carboxyl group; an amino group; an azide group; a hydrazide group; a thiol group; a disulfide group; an acid anhydride group; an oxazoline group; a vinyl group; an acrylic group; a methacrylic group; a haloacetyl group; an oxirane ring group; an oxetane ring group; a cycloalkane group, such as a cyclopropane or cyclobutane group; and a benzocyclobutene group. When two or more kinds of those reactive substituents are involved in the reaction, the two or more kinds of reactive substituents are added to the polymer.

The general formula (2) represents a polymer that may include the structural units represented by the formula (2n) and the formula (2m). In the general formula (2), the formula (2n), and the formula (2m), the same symbols as those of the general formula (1) have the same meaning.

B represents a hydrogen atom, a substituted or unsubstituted aromatic hydrocarbon group having 6 to 24 carbon atoms, a substituted or unsubstituted aromatic heterocyclic group having 3 to 17 carbon atoms, or a linked aromatic group obtained by linking a plurality of aromatic rings of the aromatic hydrocarbon group or the aromatic heterocyclic group, and Bs may be the same or different from repeating unit to repeating unit. When B represents an aromatic hydrocarbon group, an aromatic heterocyclic group, or a linked aromatic group, the group is the same as that described for L of the general formula (1) except that the groups have different valences.

“n” and “m” each represent an abundance molar ratio, and fall within the ranges of 0.5≤n≤1 and 0≤m≤0.5. “n” and “m” fall within the ranges of preferably 0.6≤n≤1 and 0≤m≤0.4, more preferably 0.7≤n≤1 and 0≤m≤0.3.

“a” represents the average number of the repeating units, and represents a number of from 2 to 1,000, preferably from 3 to 500, more preferably from 5 to 300.

An example of a case in which in the polymer represented by the general formula (1) or the general formula (2), the structural units each represented by the formula (2n) or the structural units each represented by the formula (2m) are different from repeating unit to repeating unit is a polymer represented by the following formula (3).

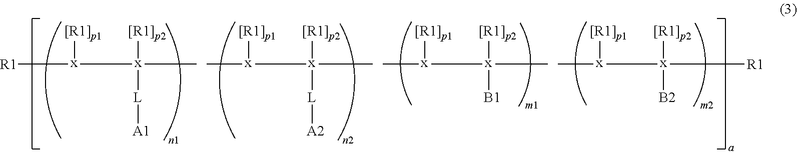

The polymer represented by the formula (3) is such an example that the polymer includes, as the structural units each represented by the formula (2n), two kinds of structural units having different substituents A1 and A2 at abundance molar ratios of n1 and n2, respectively, and includes, as the structural units each represented by the formula (2m), two kinds of structural units having different substituents B1 and B2 at abundance molar ratios of m1 and m2, respectively.

Herein, the total sum of the abundance molar ratios n1 and n2 coincides with “n” of the general formula (2), and the total sum of the abundance molar ratios m1 and m2 coincides with “m” of the general formula (2).

In the formula (3), an example in which the structural units represented by the formula (2n) and the formula (2m) are each formed of two kinds of structural units that are different from repeating unit to repeating unit is described. However, the structural units represented by the formula (2n) and the formula (2m) may be each independently formed of three or more different kinds of structural units.

It is essential that the polymer for an organic electroluminescent device of the present invention include the repeating structural unit represented by the general formula (1). The polymer preferably includes a polyphenylene main chain.

Although a group for linking the respective repeating structural units may be a single bond, a substituted or unsubstituted aromatic hydrocarbon group, a substituted or unsubstituted aromatic heterocyclic group, or a linked aromatic group obtained by linking a plurality of aromatic rings of the aromatic hydrocarbon group or the aromatic heterocyclic group as in the group L, the group is preferably a single bond or a phenylene group.

Although the polymer for an organic electroluminescent device of the present invention may include a unit except the structural unit represented by the general formula (1), the polymer desirably includes 50 mol % or more, preferably 75 mol % or more of the structural unit represented by the general formula (1).

The weight-average molecular weight of the polymer for an organic electroluminescent device of the present invention, which is 1,000 or more and 500,000 or less, is preferably 1,500 or more and 300,000 or less, more preferably 2,000 or more and 200,000 or less from the viewpoint of a balance among, for example, solubility, film formability by application, and durability against heat, charge, an exciton, or the like. The number-average molecular weight (Mn) thereof is preferably 1,000 or more and 10,000 or less, more preferably 3,000 or more and 7,000 or less, and the ratio (Mw/Mn) is preferably from 1.00 to 5.00, more preferably from 1.50 to 4.00.

Specific examples of a partial structure represented by -L-A in the general formula (1), the general formula (2), or the formula (2n) in the polymer for an organic electroluminescent device of the present invention are shown below. However, the partial structure is not limited to the exemplified partial structures.

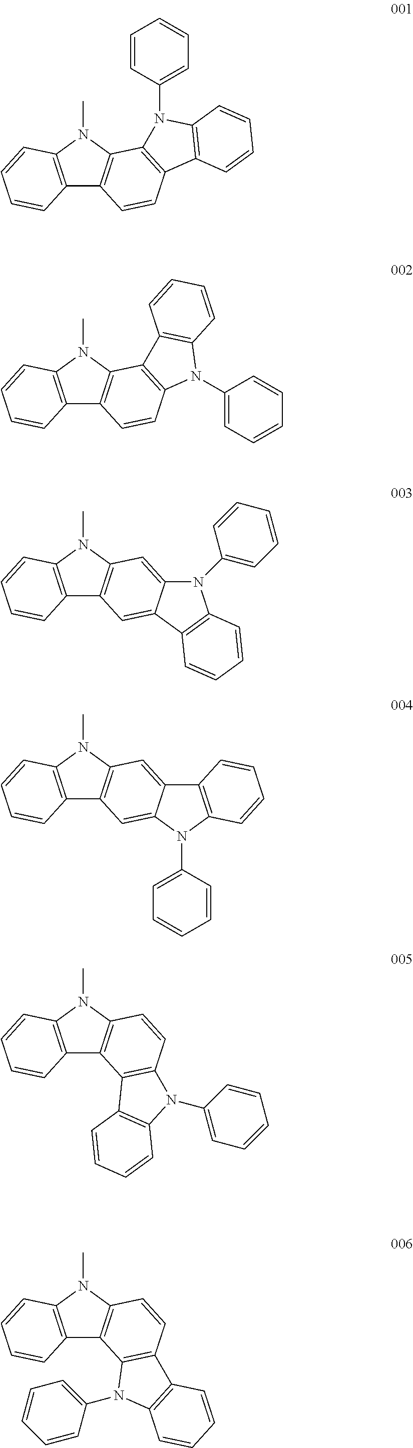

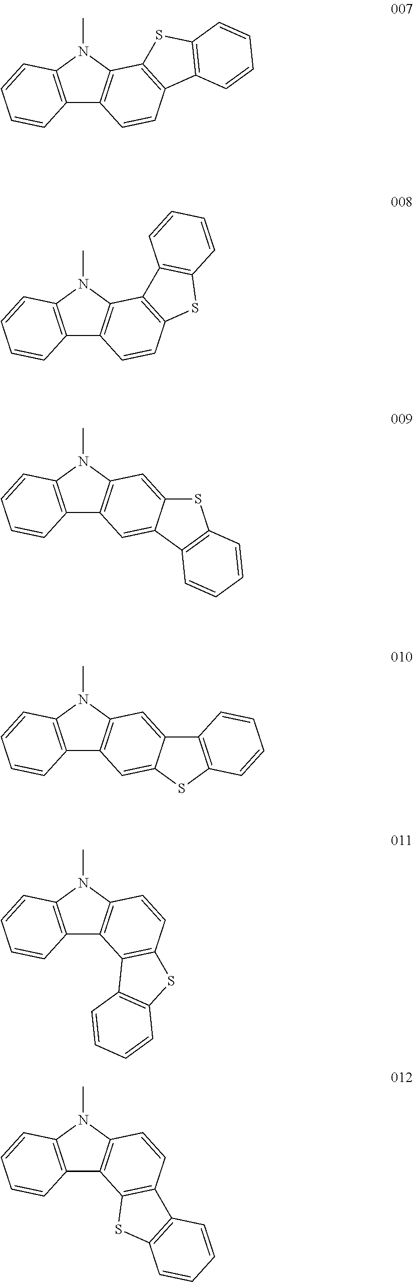

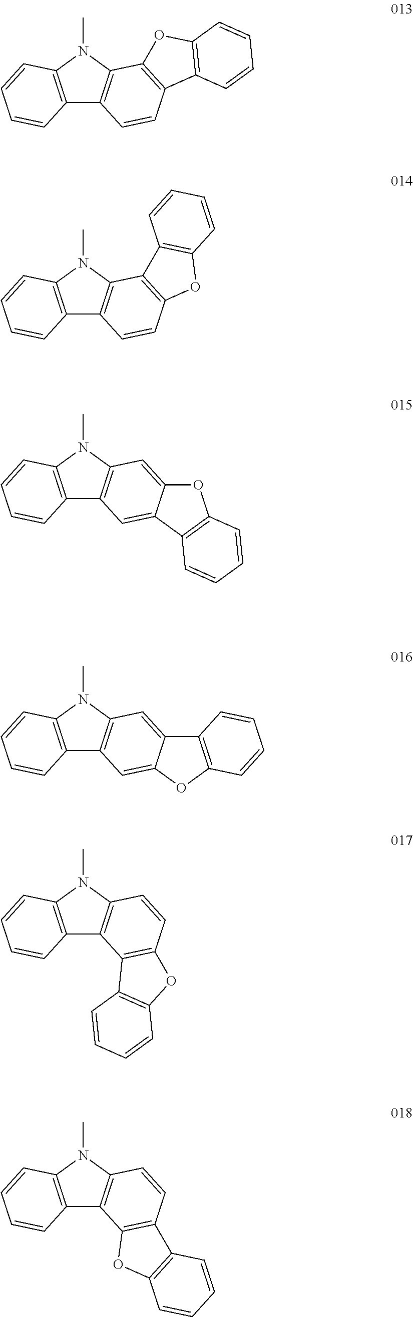

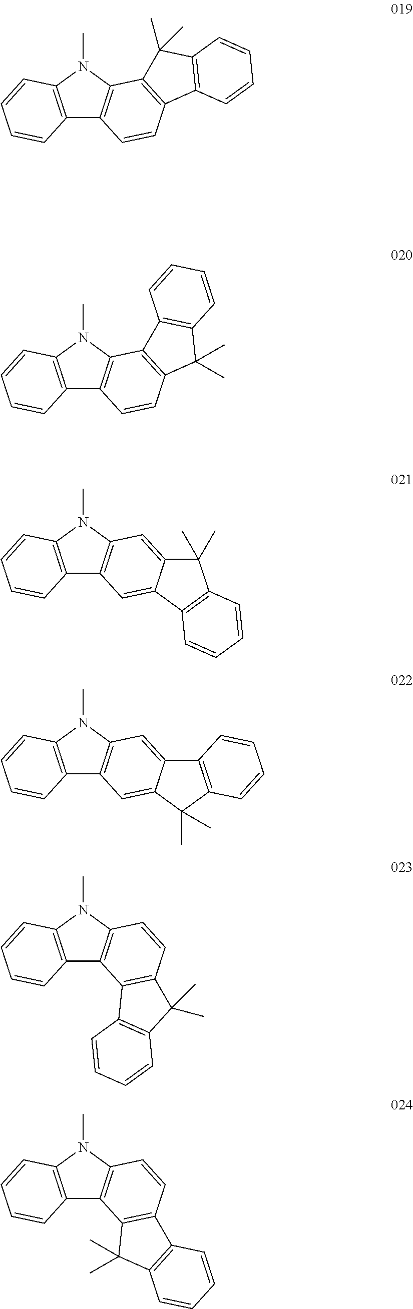

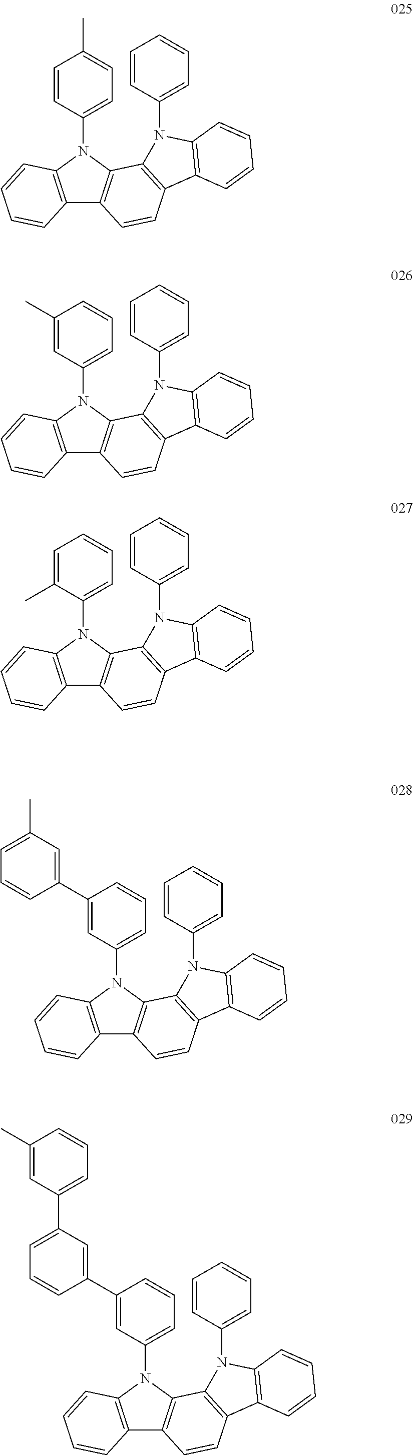

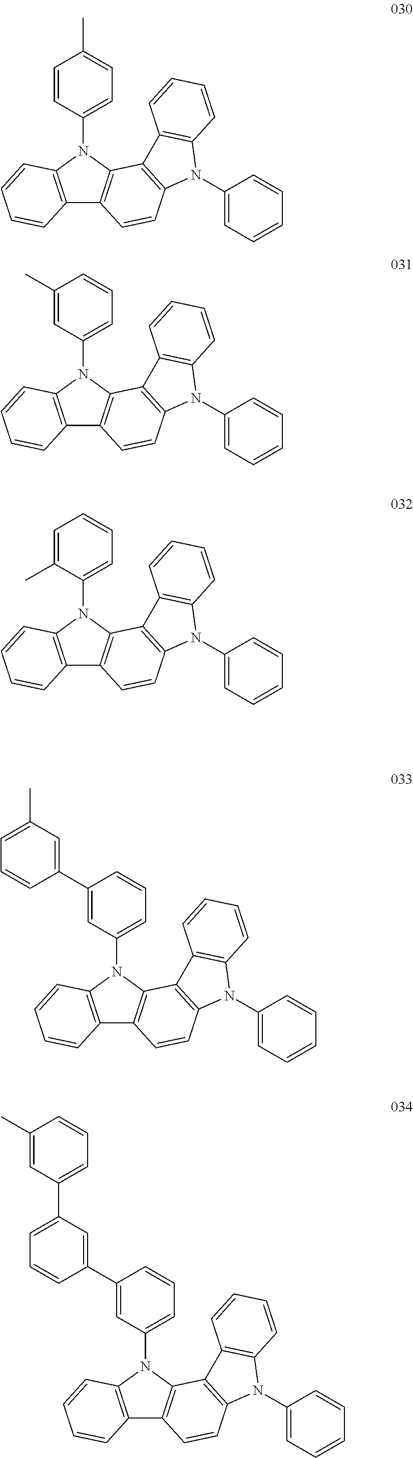

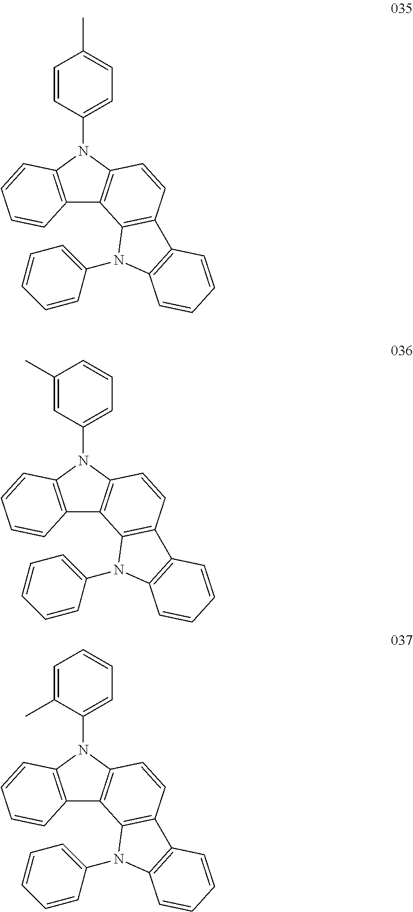

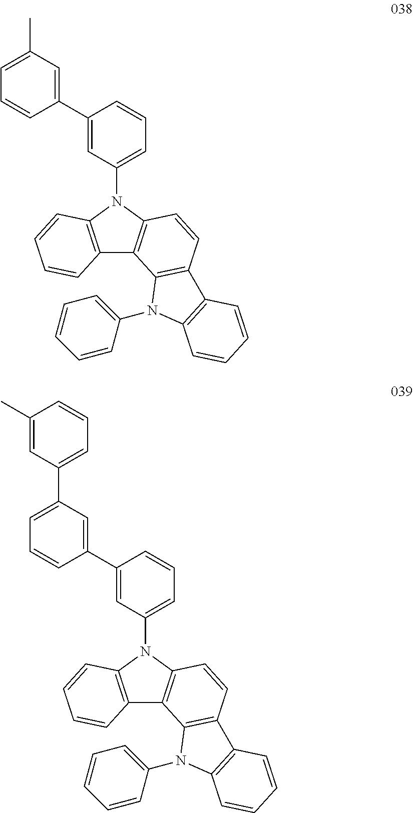

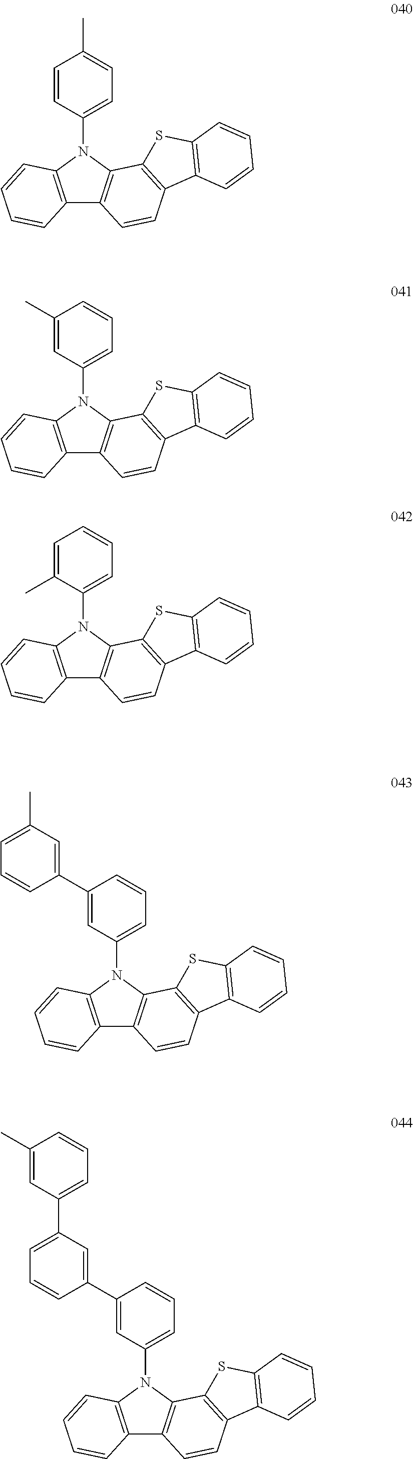

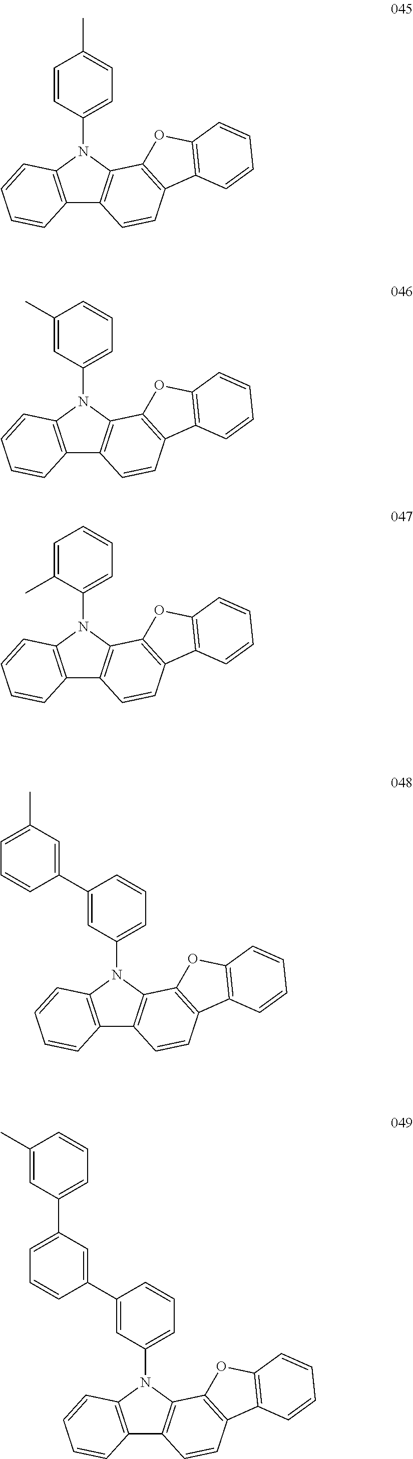

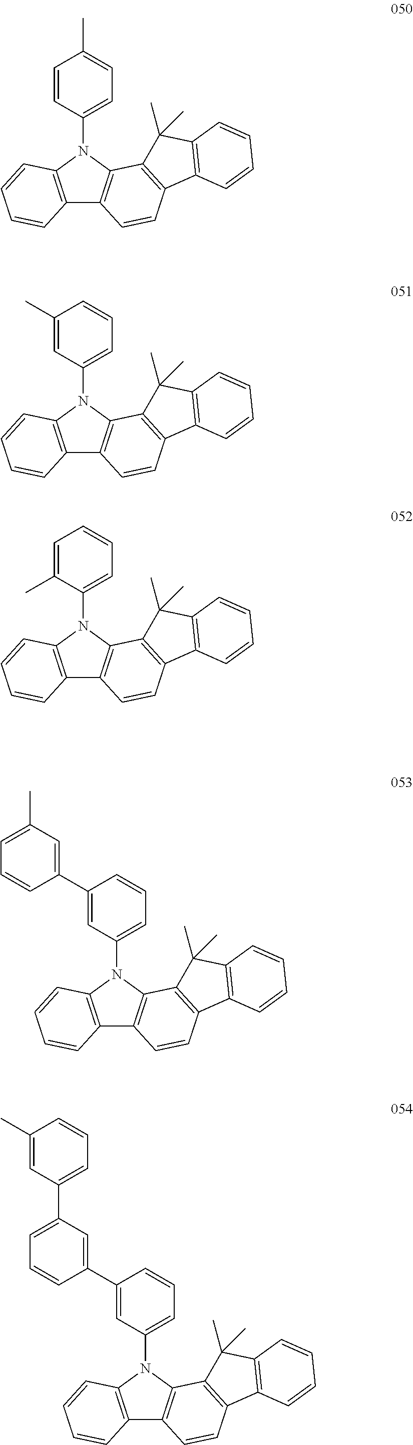

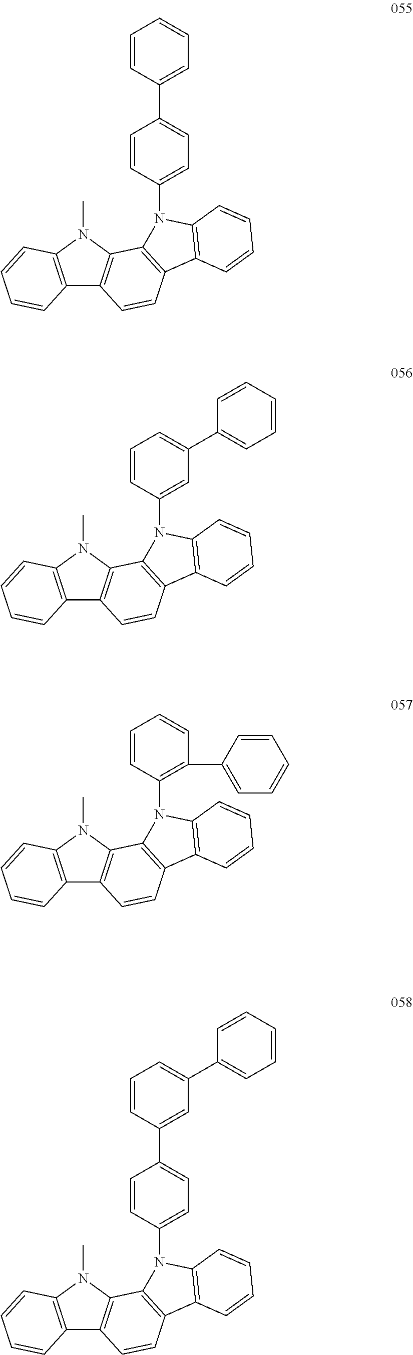

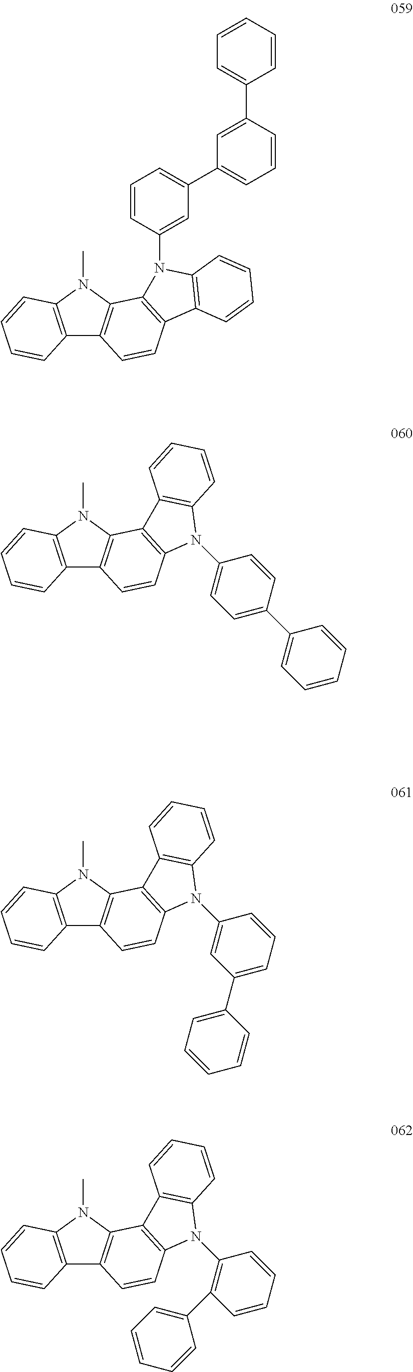

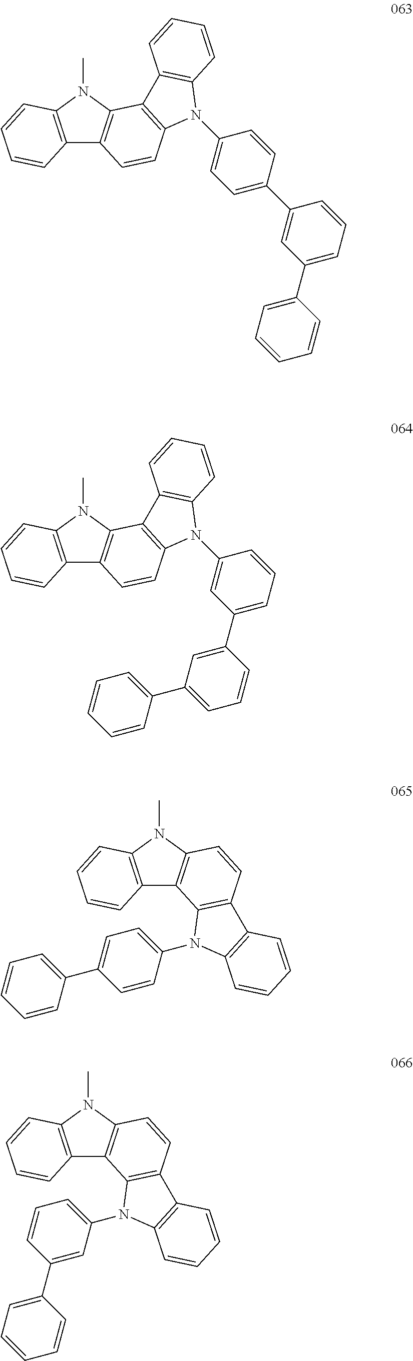

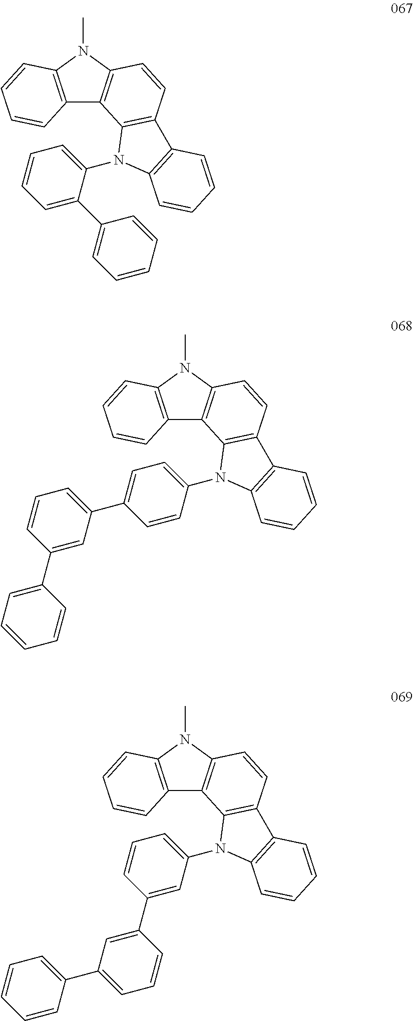

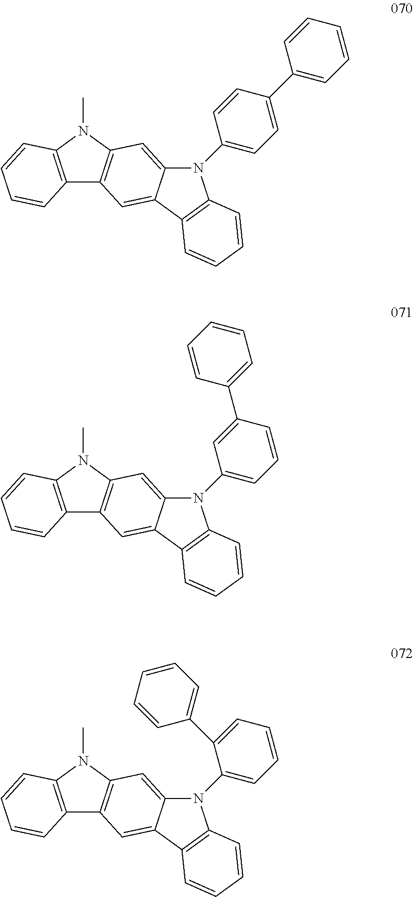

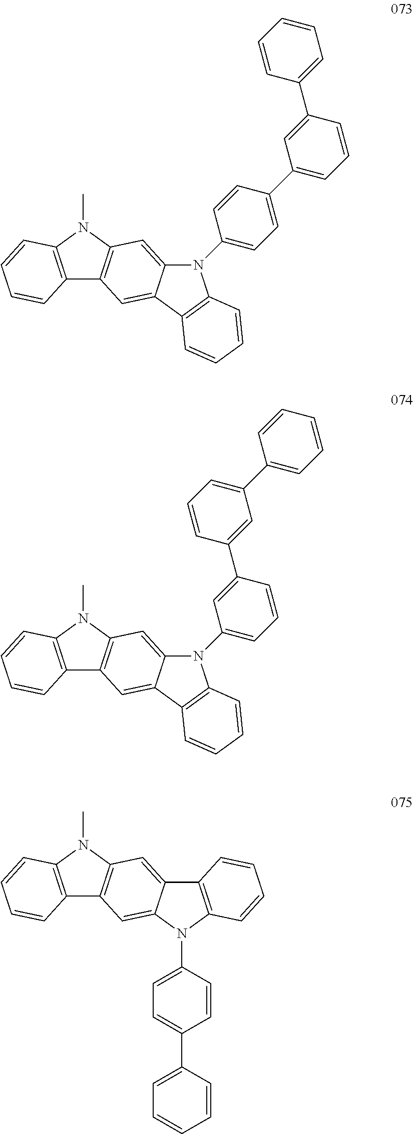

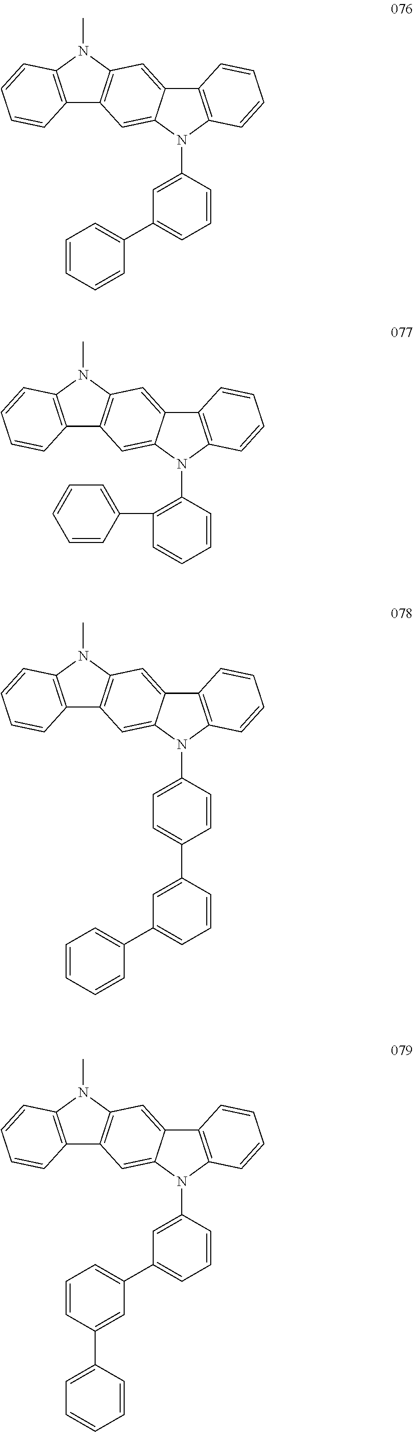

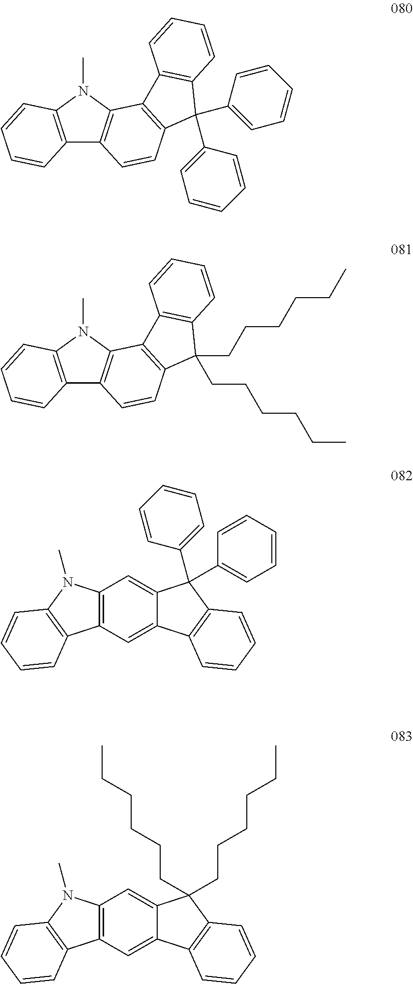

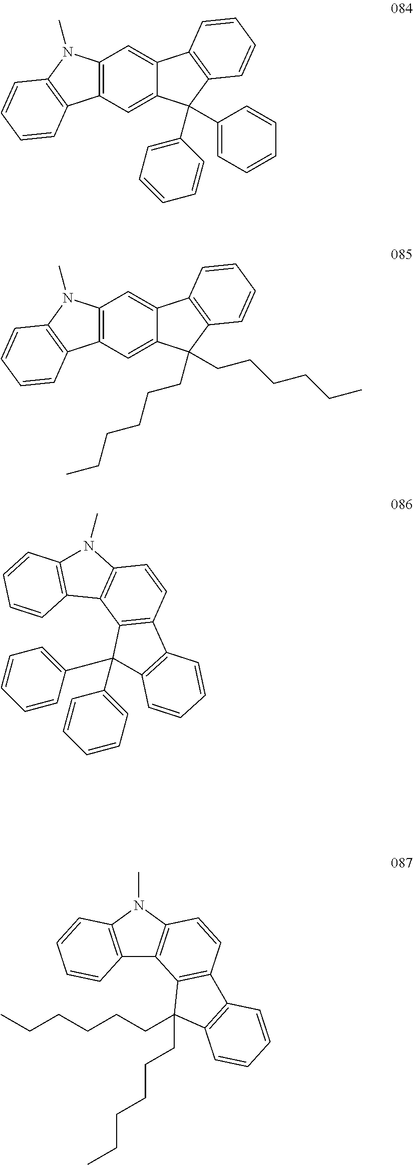

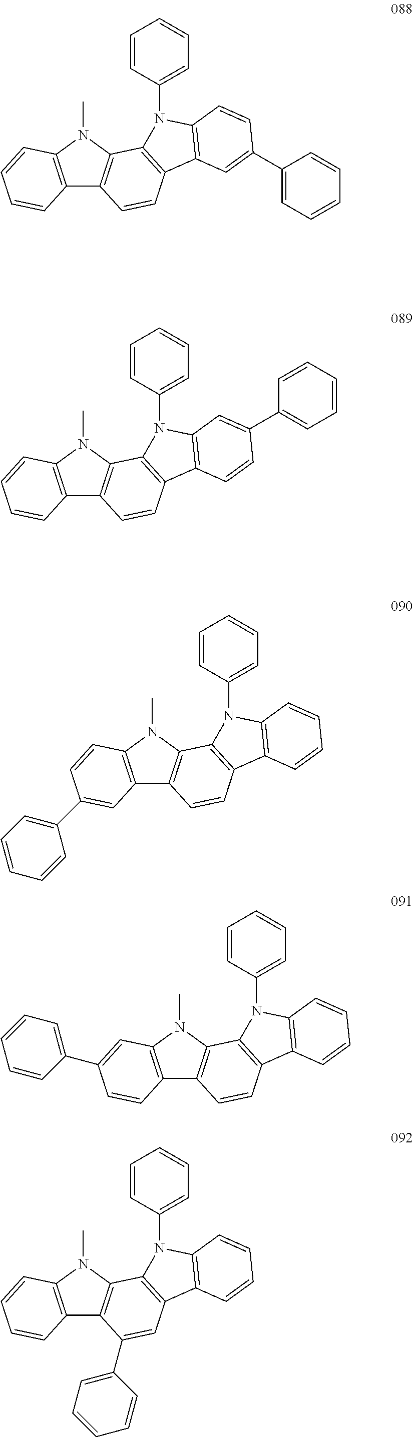

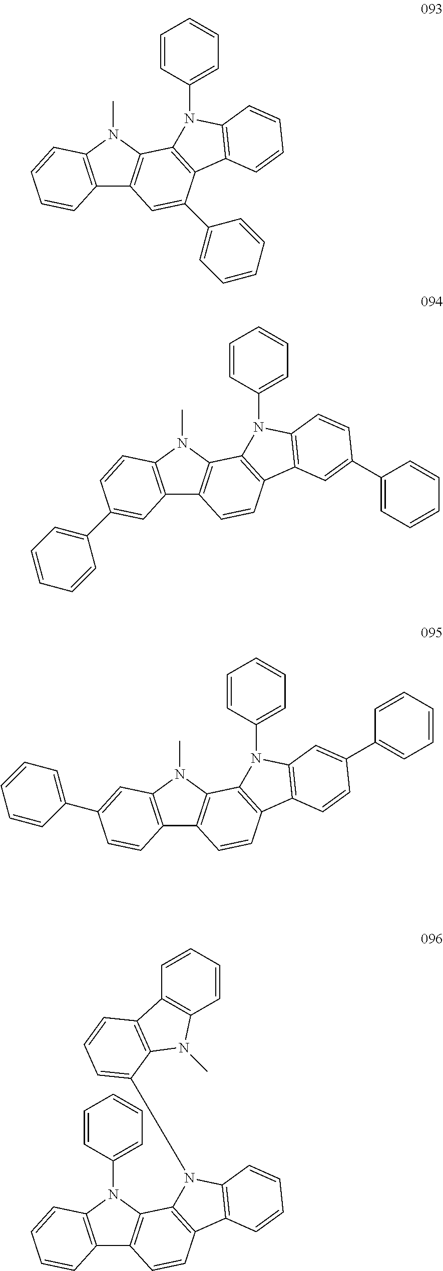

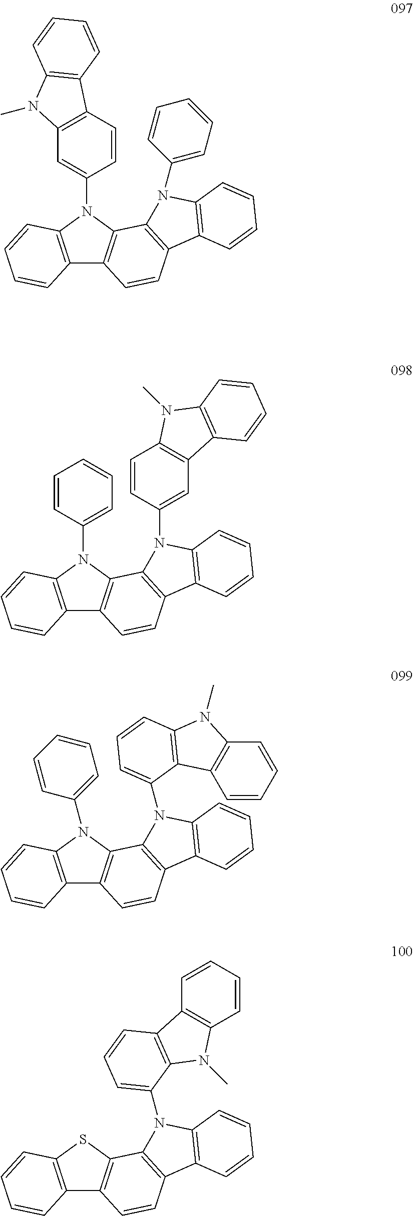

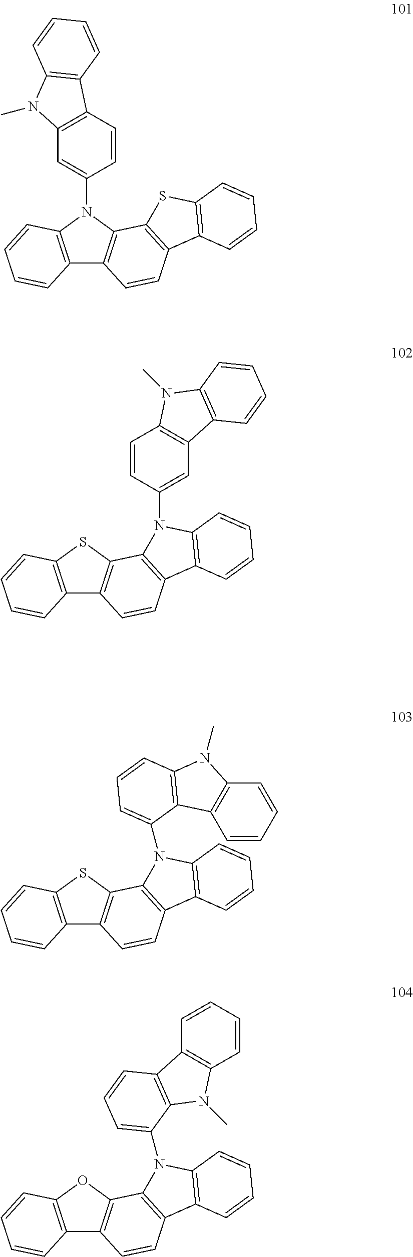

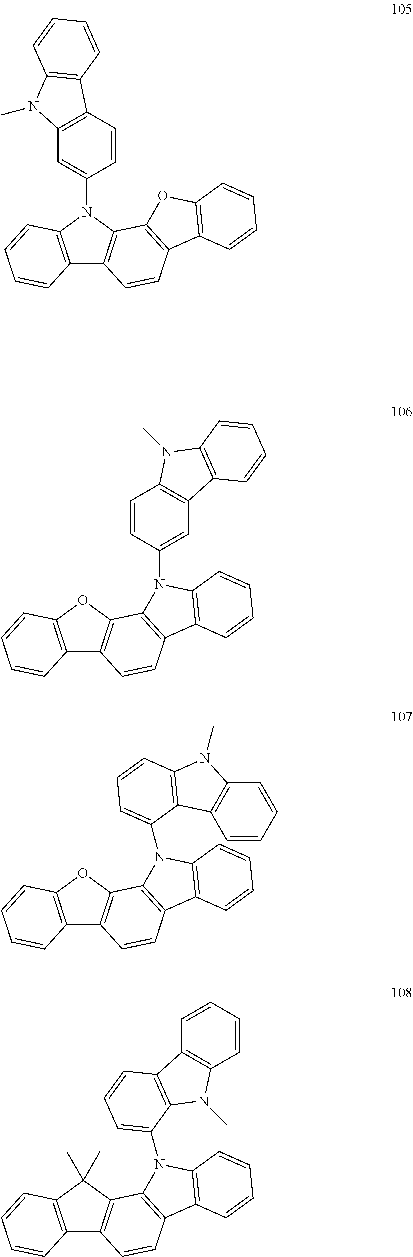

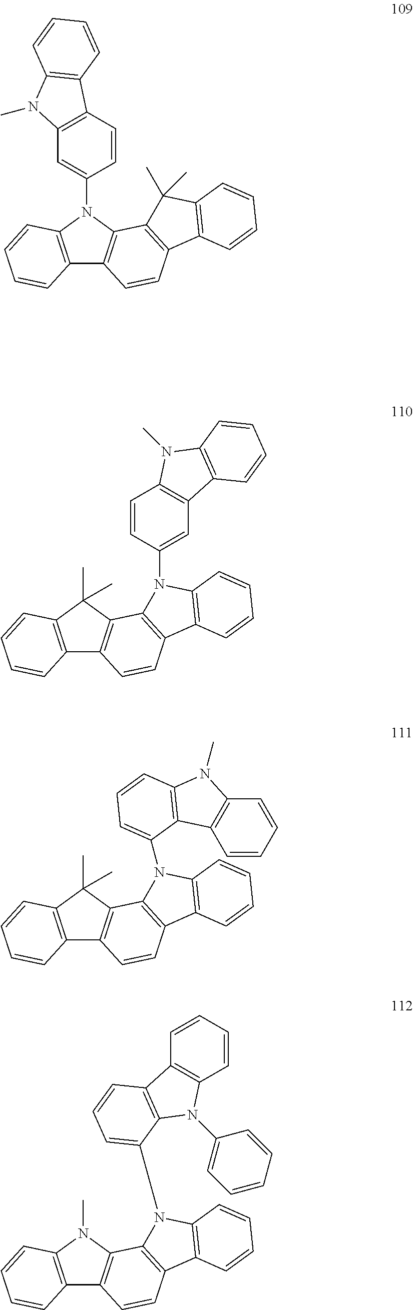

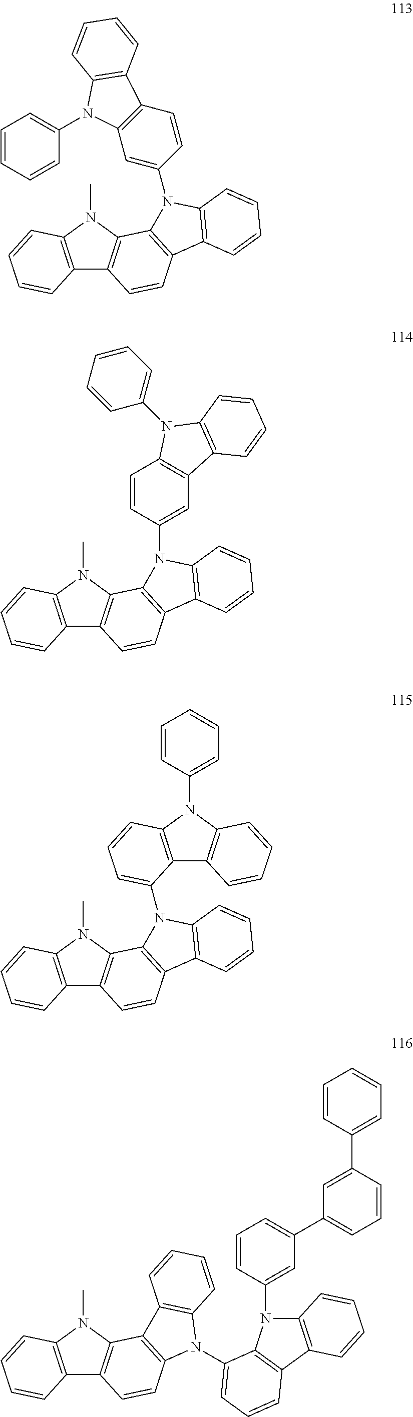

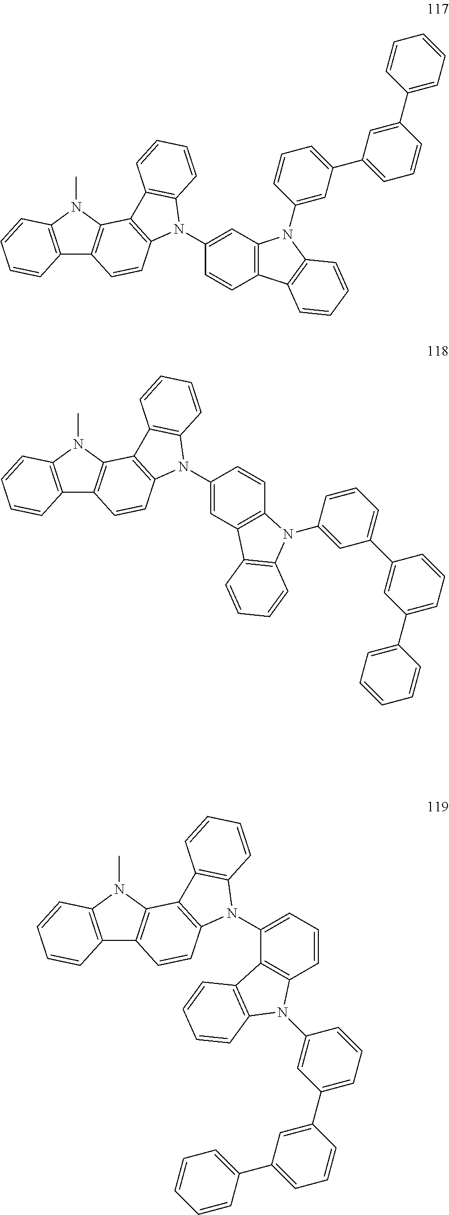

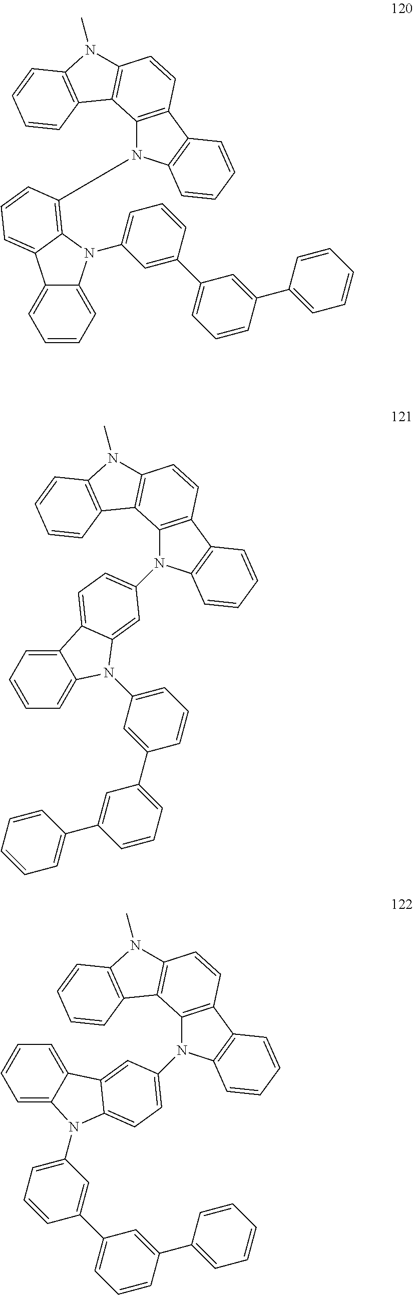

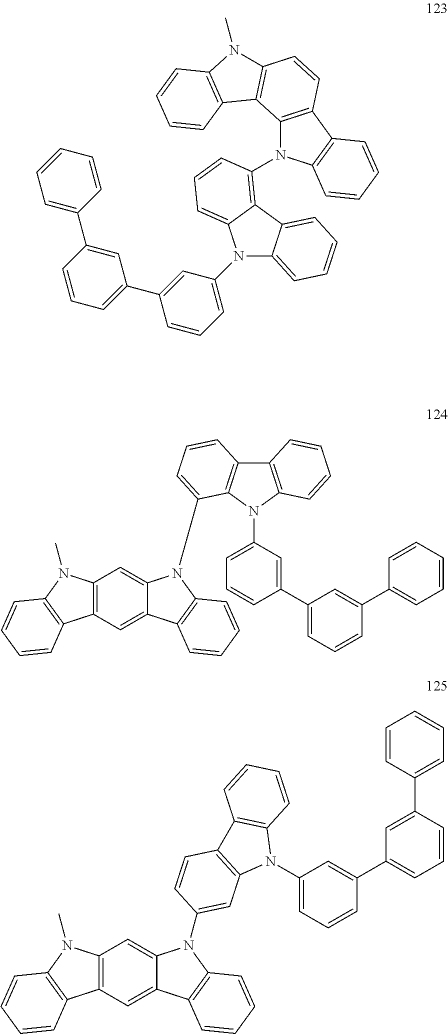

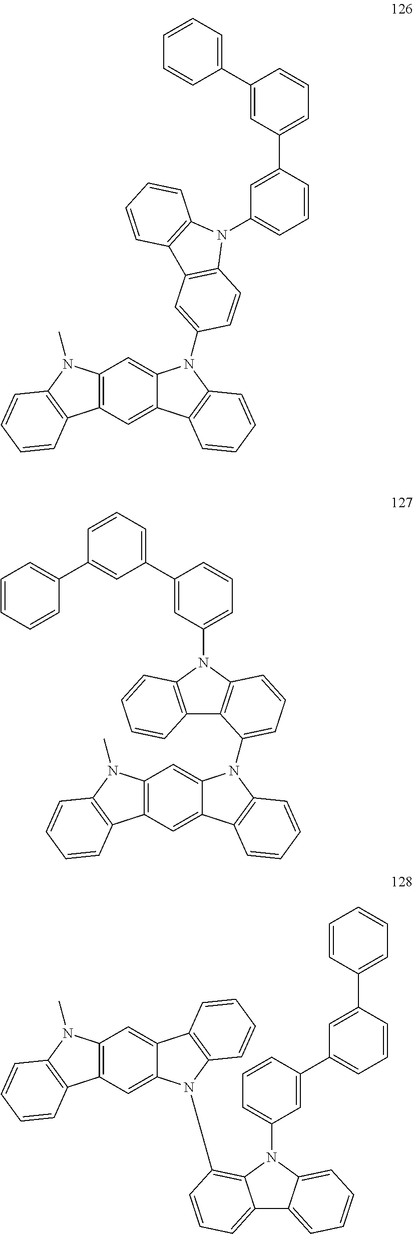

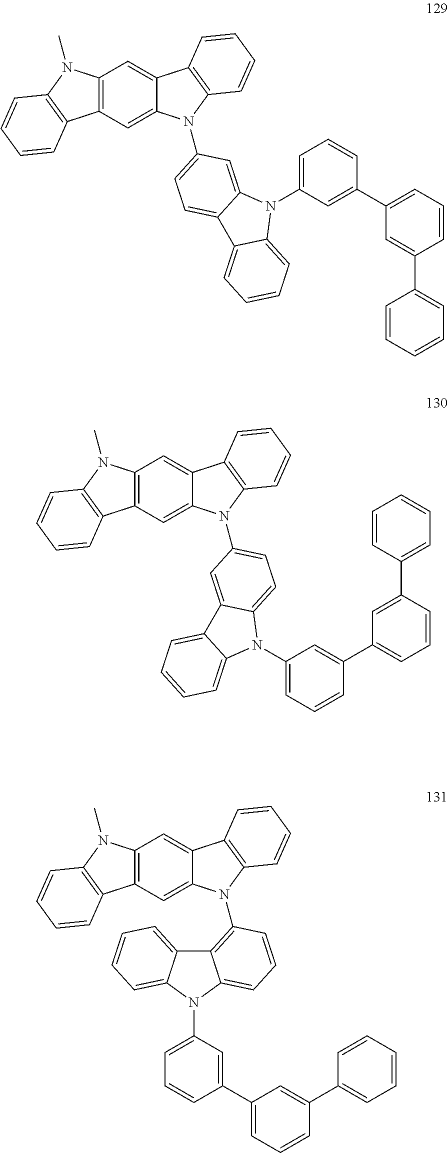

The polymer for an organic electroluminescent device of the present invention may be a polymer including, in its repeating unit, only one kind of the exemplified partial structures, or may be a polymer including the plurality of different exemplified partial structures therein. In addition, the polymer may include a repeating unit having a partial structure except the exemplified partial structures.

The polymer for an organic electroluminescent device of the present invention is characterized by including a polyphenylene skeleton in its main chain. The phenylene groups of the polyphenylene of the main chain are preferably linked to each other at a meta position or an ortho position from the viewpoint of suppressing the expansion of the orbital of the polymer to increase the T1 thereof in addition to the viewpoint of improving the dissolution stability of the polymer and the amorphous stability of a film thereof.

The polymer for an organic electroluminescent device of the present invention may have the substituent R in the polyphenylene skeleton of the main chain. However, when the polymer has the substituent R, the polymer is preferably substituted with the substituent at an ortho position with respect to the linkage of the main chain from the viewpoint of suppressing the expansion of the orbital of the polymer to increase the T1 thereof. The substituent R corresponds to R1 of the general formula (1) or the formula (2) (formula 2n or 2m). Preferred substitution positions of the substituent R are given below. However, a linked structure and the substitution position of the substituent R are not limited to the given examples.

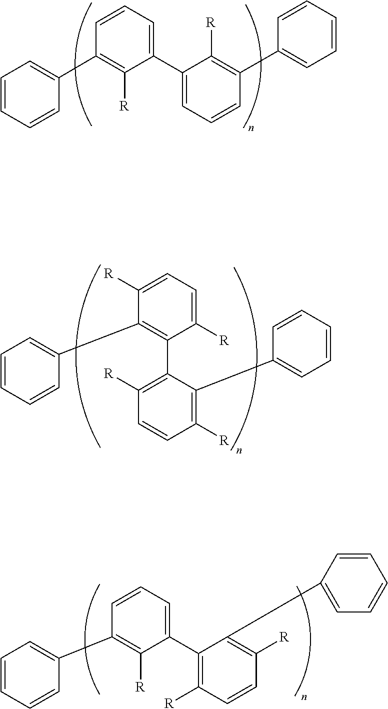

Specific examples of the structure of the polymer for an organic electroluminescent device of the present invention are shown below. However, the polymer is not limited to the exemplified polymers.

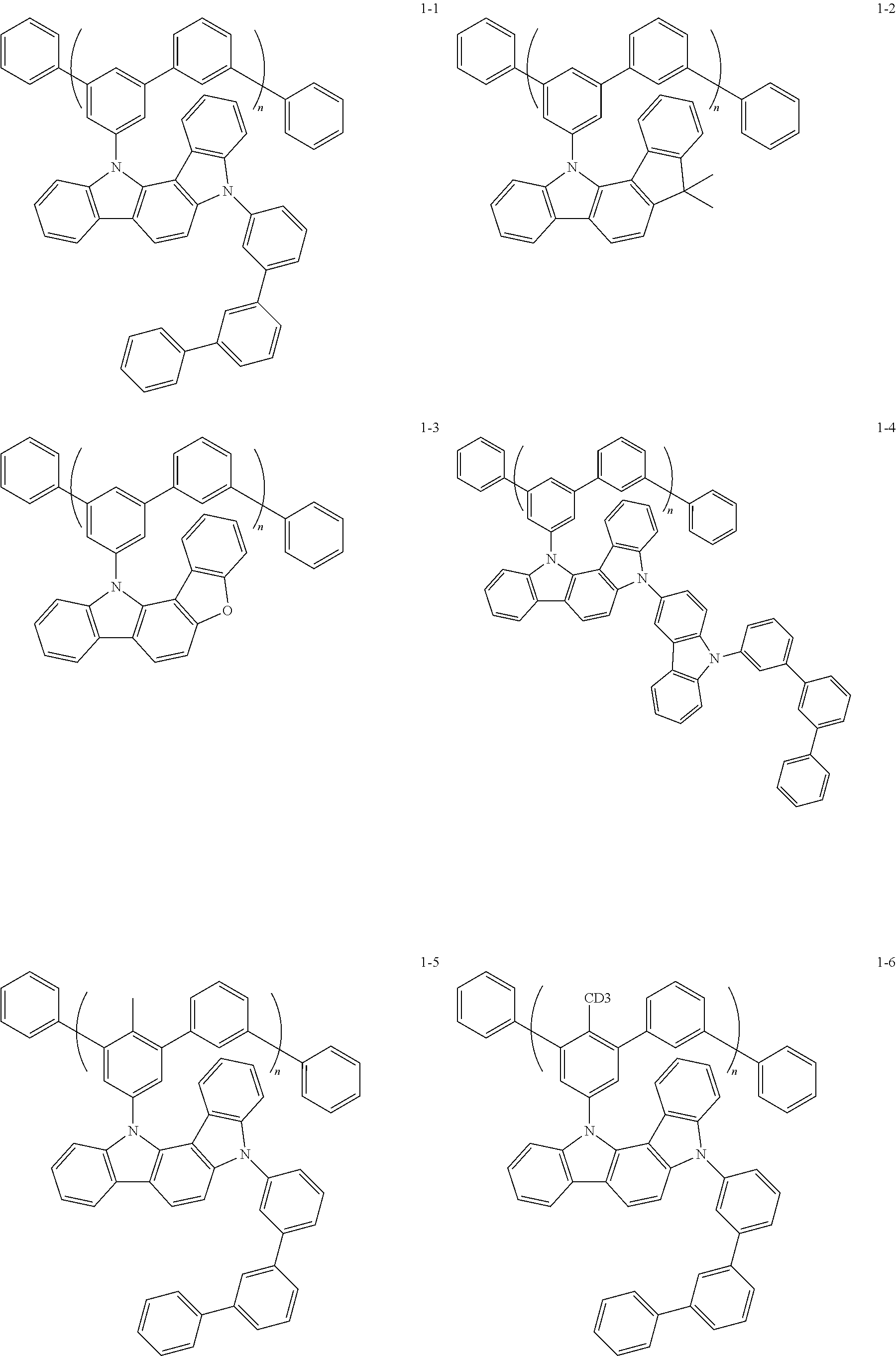

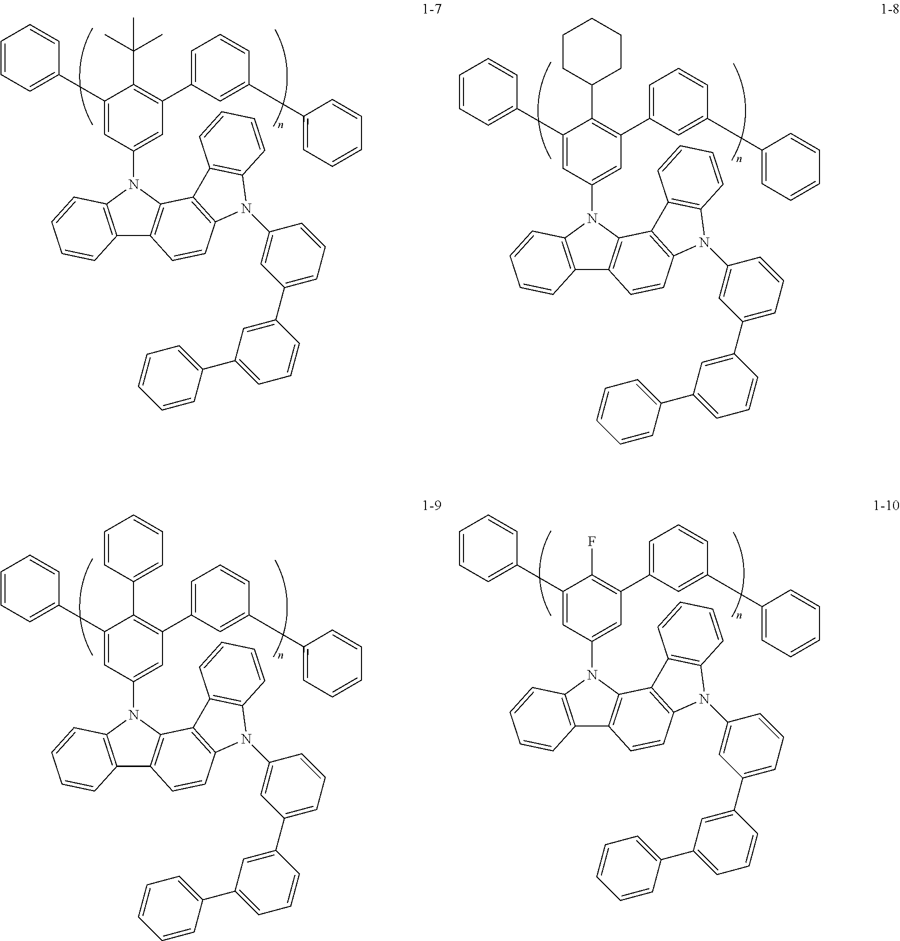

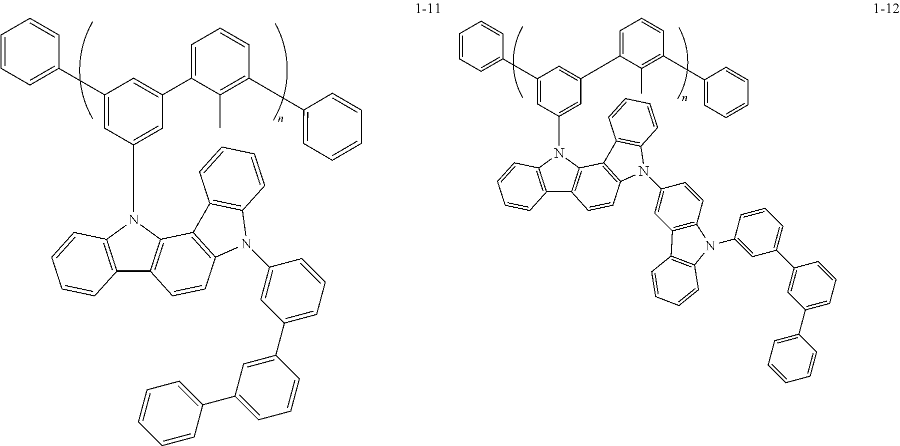

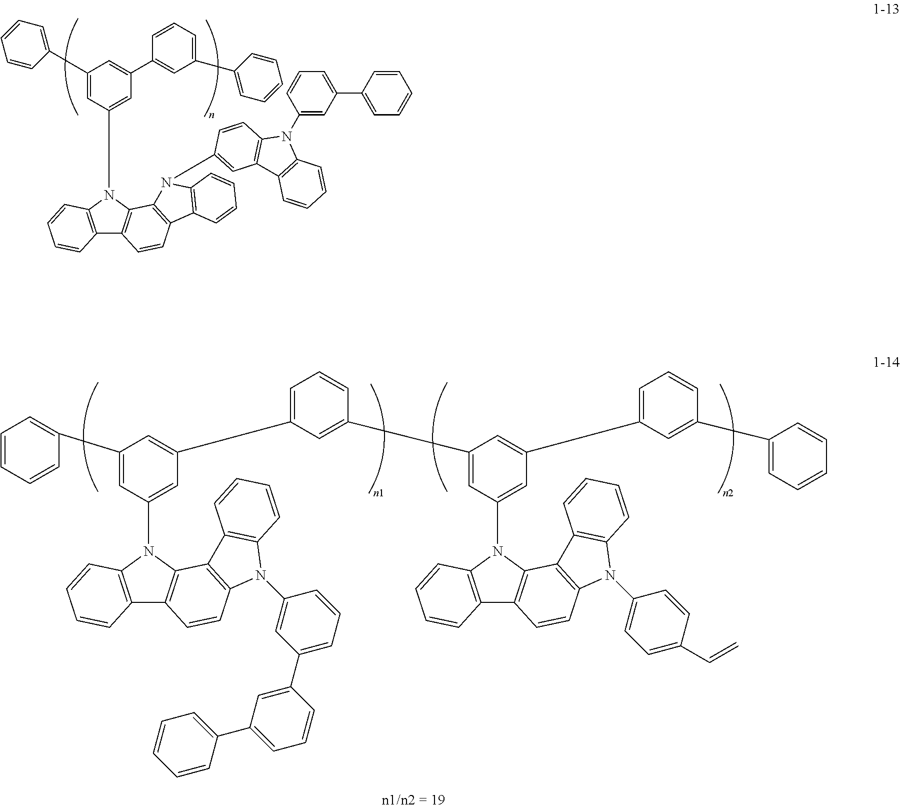

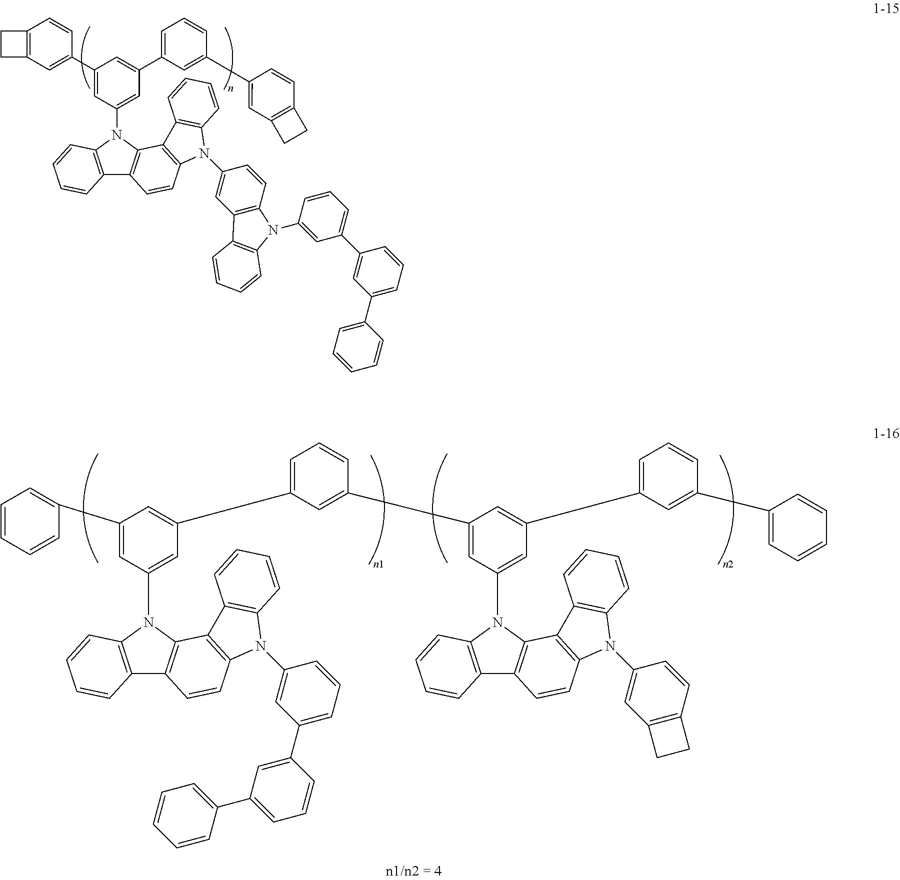

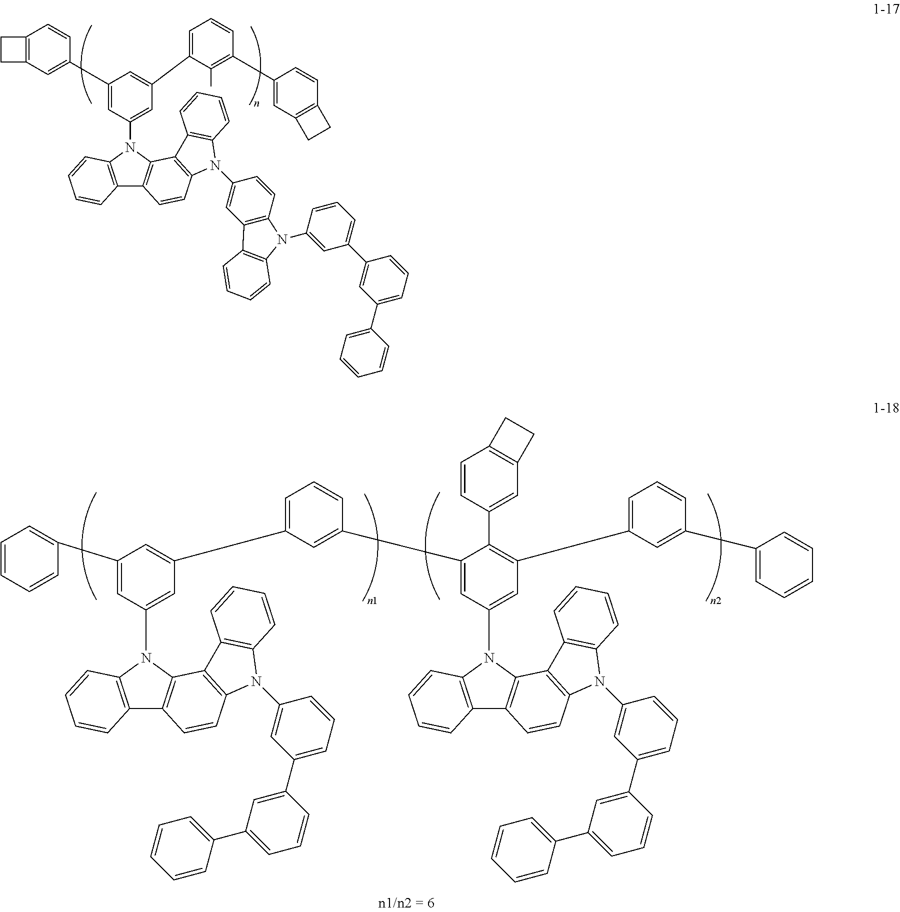

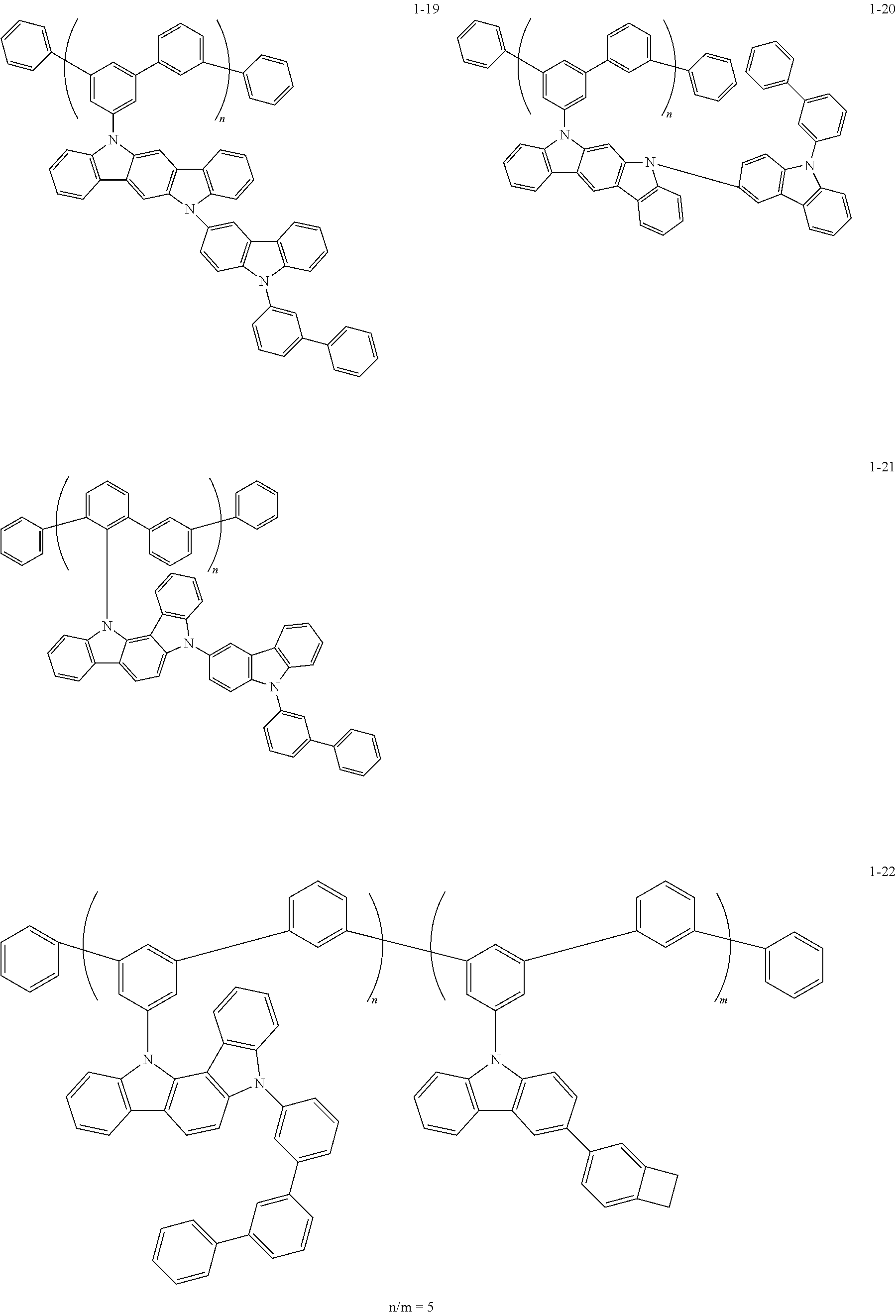

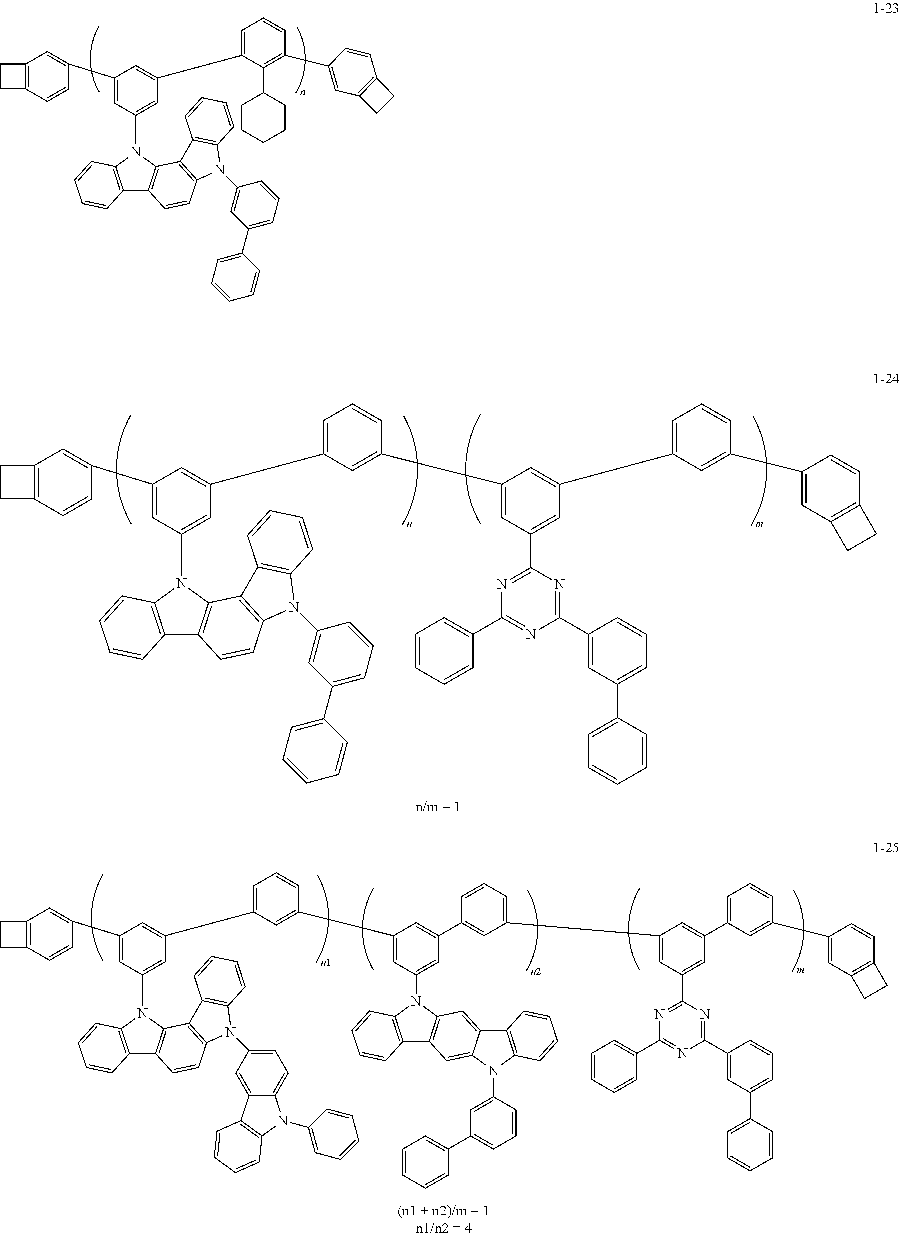

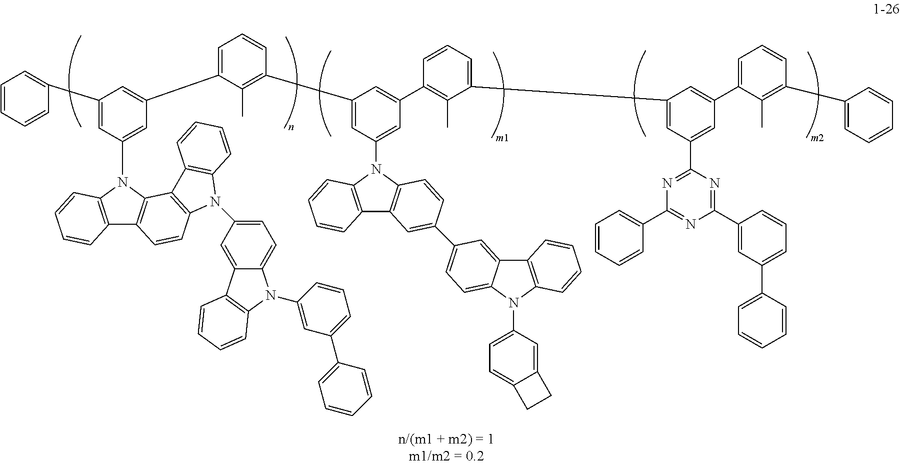

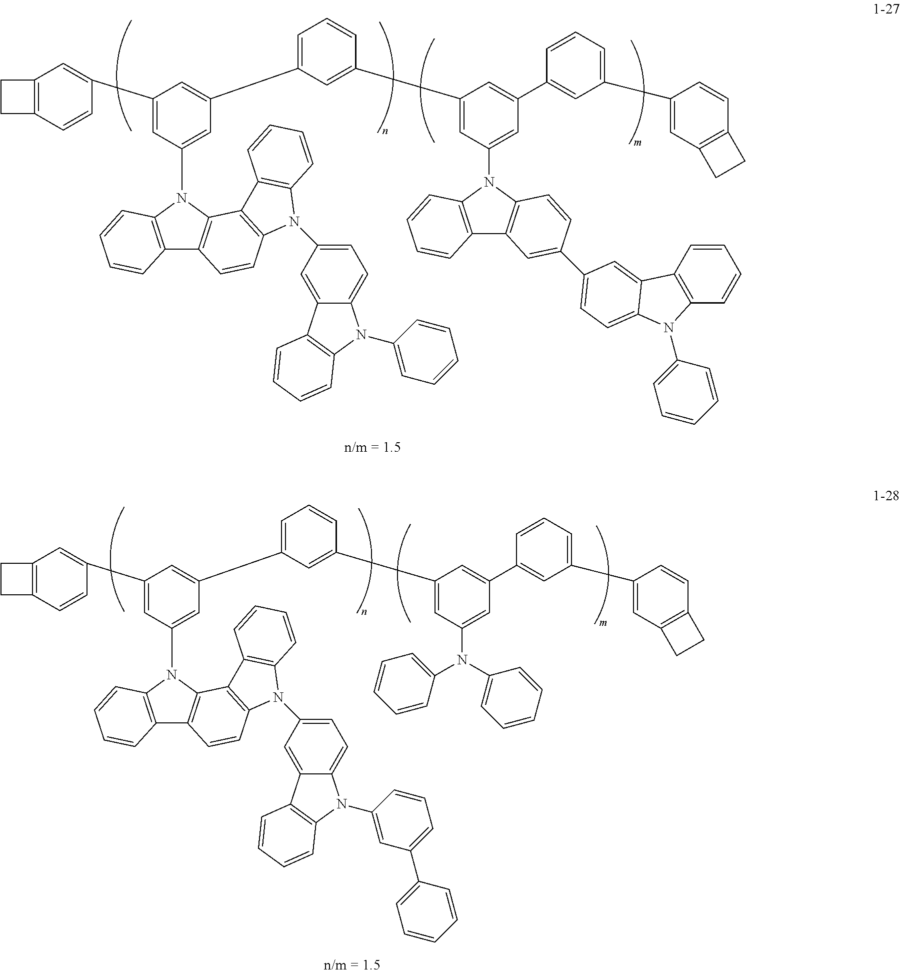

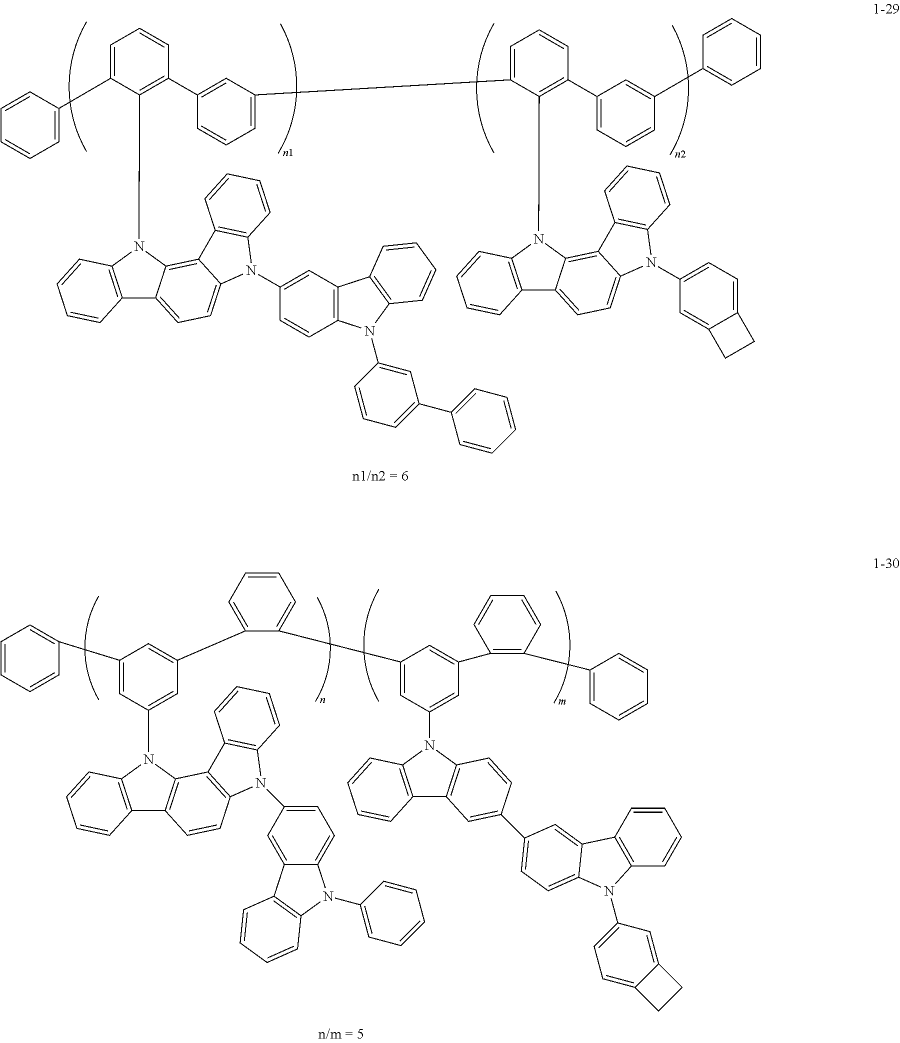

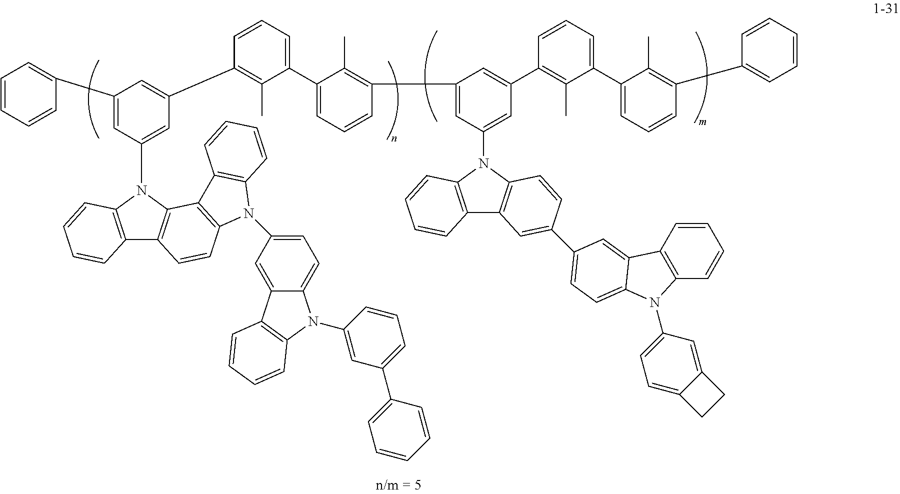

The polymer for an organic electroluminescent device of the present invention is dissolved in a general organic solvent. In particular, the solubility of the polymer in toluene at 40° C. is preferably 0.5 wt % or more, more preferably 1 wt % or more.

The polymer for an organic electroluminescent device of the present invention is preferably incorporated into at least one layer selected from a light-emitting layer, a hole-injecting layer, a hole-transporting layer, an electron-transporting layer, an electron-injecting layer, a hole-blocking layer, an electron-blocking layer, an exciton-blocking layer, and a charge-generating layer, and is more preferably incorporated into at least one layer selected from the hole-transporting layer, the electron-transporting layer, the electron-blocking layer, the hole-blocking layer, and the light-emitting layer.

Although the polymer for an organic electroluminescent device of the present invention may be used alone as a material for an organic electroluminescent device, when the plurality of polymers for an organic electroluminescent device of the present invention are used, or when the polymer is mixed with any other compound, and the mixture is used as a material for an organic electroluminescent device, the function of the polymer can be further improved, or insufficient characteristics thereof can be compensated. Although a preferred compound that may be used by being mixed with the polymer for an organic electroluminescent device of the present invention is not particularly limited, examples thereof include a hole-injecting layer material, a hole-transporting layer material, an electron-blocking layer material, a light-emitting layer material, a hole-blocking layer material, an electron-transporting layer material, and a conductive polymer material each of which is used as a material for an organic electroluminescent device. The term “light-emitting layer material” as used herein includes a host material having a hole-transporting property, an electron-transporting property, or a bipolar property, and a light-emitting material, such as a phosphorescent material, a fluorescent material, or a thermally activated delayed fluorescent material.

Although a method of forming the material for an organic electroluminescent device of the present invention into a film is not particularly limited, a preferred film formation method out of such methods is, for example, a printing method. Specific examples of the printing method include, but not limited to, a spin coating method, a bar coating method, a spray method, and an inkjet method.

When the material for an organic electroluminescent device of the present invention is formed into a film by using the printing method, an organic layer may be formed by: applying a solution obtained by dissolving or dispersing the material for an organic electroluminescent device of the present invention in a solvent (also referred to as “composition for an organic electroluminescent device”) onto a substrate; and then volatilizing the solvent through drying by heating. At this time, the solvent to be used is not particularly limited, but is preferably as follows: the material is uniformly dispersed or dissolved in the solvent, and the solvent is hydrophobic. One kind of solvent may be used, or a mixture of two or more kinds of solvents may be used.

The solution obtained by dissolving or dispersing the material for an organic electroluminescent device of the present invention in the solvent may contain one or two or more kinds of materials for an organic electroluminescent device as compounds except the material of the present invention, and may contain an additive, such as a surface modifier, a dispersant, or a radical-trapping agent, or a nanofiller to the extent that the characteristics of the material of the present invention are not impaired.

Next, the structure of a device to be produced by using the material of the present invention is described with reference to the drawings. However, the structure of the organic electroluminescent device of the present invention is not limited thereto.

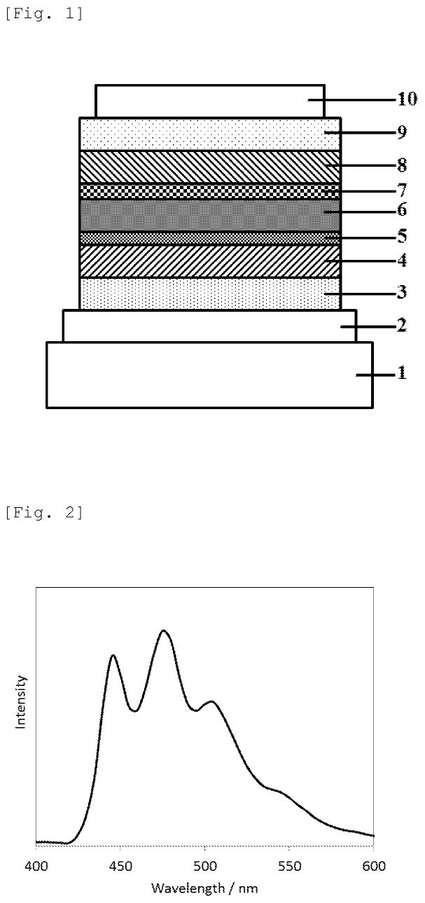

FIG. 1 is a sectional view for illustrating an example of the structure of a general organic electroluminescent device to be used in the present invention. Reference numeral 1 represents a substrate, reference numeral 2 represents an anode, reference numeral 3 represents a hole-injecting layer, reference numeral 4 represents a hole-transporting layer, reference numeral 5 represents an electron-blocking layer, reference numeral 6 represents a light-emitting layer, reference numeral 7 represents a hole-blocking layer, reference numeral 8 represents an electron-transporting layer, reference numeral 9 represents an electron-injecting layer, and reference numeral 10 represents a cathode. The organic EL device of the present invention may include an exciton-blocking layer adjacent to the light-emitting layer instead of the electron-blocking layer or the hole-blocking layer. The exciton-blocking layer may be inserted into any one of the anode side and cathode side of the light-emitting layer, and such layers may be simultaneously inserted into both the sides. In addition, the device may include a plurality of light-emitting layers having different wavelengths. The organic electroluminescent device of the present invention, which includes the anode, the light-emitting layer, and the cathode as its essential layers, desirably includes a hole-injecting/transporting layer and an electron-injecting/transporting layer in addition to the essential layers, and more desirably includes the hole-blocking layer between the light-emitting layer and the electron-injecting/transporting layer, and the electron-blocking layer between the light-emitting layer and the hole-injecting/transporting layer. The term “hole-injecting/transporting layer” means any one or both of the hole-injecting layer and the hole-transporting layer, and the term “electron-injecting/transporting layer” means any one or both of the electron-injecting layer and the electron-transporting layer.

It is possible to adopt a reverse structure as compared to FIG. 1, that is, the reverse structure being formed by laminating the layers on the substrate 1 in the order of the cathode 10, the electron-injecting layer 9, the electron-transporting layer 8, the hole-blocking layer 7, the light-emitting layer 6, the electron-blocking layer 5, the hole-transporting layer 4, the hole-injecting layer 3, and the anode 2. In this case as well, some layers may be added or eliminated as required.

—Substrate—

The organic electroluminescent device of the present invention is preferably supported by the substrate. The substrate is not particularly limited, and for example, the substrate may be an inorganic material, such as glass, quartz, alumina, or SUS, or may be an organic material, such as polyimide, PEN, PEEK, or PET. In addition, the substrate may be of a hard plate shape, or may be of a flexible film shape.

—Anode—

A material formed of a metal, an alloy, an electrically conductive compound, or a mixture thereof, which has a large work function (4 eV or more), is preferably used as an anode material in the organic electroluminescent device. Specific examples of such electrode material include metals, such as Au, and conductive transparent materials, such as CuI, indium tin oxide (ITO), SnO₂, and ZnO. In addition, it may be possible to use an amorphous material, such as IDIXO (In₂O₃—ZnO), which may be used for producing a transparent conductive film. In order to produce the anode, it may be possible to form any of those electrode materials into a thin film by using a method such as vapor deposition or sputtering and form a pattern having a desired shape thereon by photolithography. Alternatively, in the case of not requiring high pattern accuracy (about 100 μm or more), a pattern may be formed via a mask having a desired shape when any of the above-mentioned electrode materials is subjected to vapor deposition or sputtering. Alternatively, when a coatable substance, such as an organic conductive compound, is used, it is also possible to use a wet film-forming method, such as a printing method or a coating method. When luminescence is taken out from the anode, the transmittance of the anode is desirably controlled to more than 10%. In addition, the anode preferably has a sheet resistance of several hundreds of ohms per square or less. The thickness of the film is, depending on its material, selected from the range of typically from 10 nm to 1,000 nm, preferably from 10 nm to 200 nm.

—Cathode—

Meanwhile, a material formed of a metal (referred to as electron-injecting metal), an alloy, an electrically conductive compound, or a mixture thereof, which has a small work function (4 eV or less), is used as a cathode material. Specific examples of such electrode material include aluminum, sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, and rare earth metals. Of those, a mixture of an electron-injecting metal and a second metal, which is a stable metal having a work function value larger than that of the former metal, such as a magnesium/silver mixture, a magnesium/aluminum mixture, a magnesium/indium mixture, an aluminum/aluminum oxide (Al₂O₃) mixture, or a lithium/aluminum mixture, or aluminum is suitable in terms of an electron-injecting property and durability against oxidation or the like. The cathode may be produced through the formation of any such cathode material into a thin film by a method such as deposition or sputtering. In addition, the cathode preferably has a sheet resistance of several hundreds of ohms per square or less, and its thickness is selected from the range of typically from 10 nm to 5 μm, preferably from 50 nm to 200 nm. A case in which any one of the anode and cathode of the organic electroluminescent device is transparent or semi-transparent so as to transmit emitted light is convenient because the light emission luminance of the device is improved.

In addition, after any of the above-mentioned metals is formed into a film having a thickness of from 1 nm to 20 nm as a cathode, any of the conductive transparent materials mentioned in the description of the anode is formed into a film on the cathode, thereby being able to produce a transparent or semi-transparent cathode. Then, by applying this, it is possible to produce a device in which both the anode and the cathode have transparency.

—Light-Emitting Layer—

The light-emitting layer is a layer configured to emit light after the production of an exciton by the recombination of a hole and an electron injected from the anode and the cathode, respectively, and the light-emitting layer contains a light-emitting dopant material and a host material.

The polymer for an organic electroluminescent device of the present invention is suitably used as a host material in the light-emitting layer. When the polymer for an organic electroluminescent device of the present invention is used as a host material, the polymer may be used alone, or the plurality of polymers may be used as a mixture. Further, one or a plurality of kinds of host materials except the material of the present invention may be used in combination.

The host material that may be used is not particularly limited, but is preferably a compound, which has a hole-transporting ability and an electron-transporting ability, prevents the lengthening of the wavelength of emitted light, and has a high glass transition temperature.

Such other host material is made public by many patent literatures and the like, and hence may be selected from the literatures and the like. The host material is not particularly limited, and specific examples thereof include an indole derivative, a carbazole derivative, an indolocarbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, an anthraquinodimethane derivative, an anthrone derivative, a diphenylquinone derivative, a thiopyran dioxide derivative, a heterocyclic tetracarboxylic acid anhydride, such as naphthalene perylene, a phthalocyanine derivative, various metal complexes typified by a metal complex of an 8-quinolinol derivative, metal phthalocyanine, and a metal complex of a benzoxazole or benzothiazole derivative, and polymer compounds, such as a polysilane-based compound, a poly(N-vinylcarbazole) derivative, an aniline-based copolymer, a thiophene oligomer, a polythiophene derivative, a polyphenylene vinylene derivative, and a polyfluorene derivative.

When the polymer for an organic electroluminescent device of the present invention is used as a light-emitting layer material, a method of forming the polymer into a film may be a method including vapor-depositing the polymer from a deposition source, or may be a printing method including dissolving the polymer in a solvent to provide a solution, and then applying the solution onto the hole-injecting/transporting layer or onto the electron-blocking layer, followed by drying. The light-emitting layer may be formed by any such method.

When the polymer for an organic electroluminescent device of the present invention is used as a light-emitting layer material, and is vapor-deposited to form an organic layer, any other host material and the dopant may be vapor-deposited from different deposition sources together with the material of the present invention, or a plurality of host materials and the dopant may be simultaneously vapor-deposited from one deposition source by preliminarily mixing the material of the present invention, the other host material, and the dopant before the deposition to provide a preliminary mixture.

When the polymer for an organic electroluminescent device of the present invention is used as a light-emitting layer material, and the light-emitting layer is formed by the printing method, the solution to be applied may contain, for example, a host material, the dopant material, and an additive in addition to the polymer for an organic electroluminescent device of the present invention. When a film is formed by applying the solution containing the polymer for an organic electroluminescent device of the present invention, it is preferred that a material to be used in the hole-injecting/transporting layer serving as a ground for the film have low solubility in the solvent used in the light-emitting layer solution, or be insolubilized therein by crosslinking or polymerization.

The light-emitting dopant material is not particularly limited as long as the material is a light-emitting material, and specific examples thereof include a fluorescent light-emitting dopant, a phosphorescent light-emitting dopant, and a delayed fluorescent light-emitting dopant. Of those, a phosphorescent light-emitting dopant and a delayed fluorescent light-emitting dopant are preferred in terms of luminous efficiency. In addition, only one kind of those light-emitting dopants may be incorporated, and two or more kinds thereof may be incorporated.

The phosphorescent light-emitting dopant desirably contains an organometallic complex containing at least one kind of metal selected from ruthenium, rhodium, palladium, silver, rhenium, osmium, iridium, platinum, and gold. Specifically, an iridium complex described in J. Am. Chem. Soc. 2001, 123, 4304, or JP 2013-530515 A is suitably used, but the dopant is not limited thereto. In addition, the content of the phosphorescent light-emitting dopant material is preferably from 0.1 wt % to 30 wt %, more preferably from 1 wt % to 20 wt % with respect to the host material.

The phosphorescent light-emitting dopant material is not particularly limited, but specific examples thereof include the following materials.

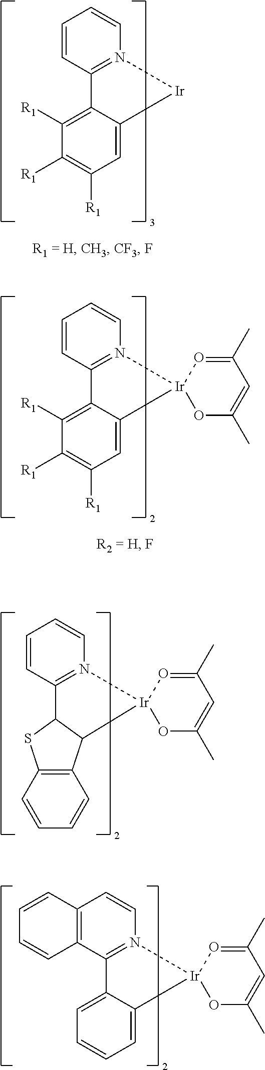

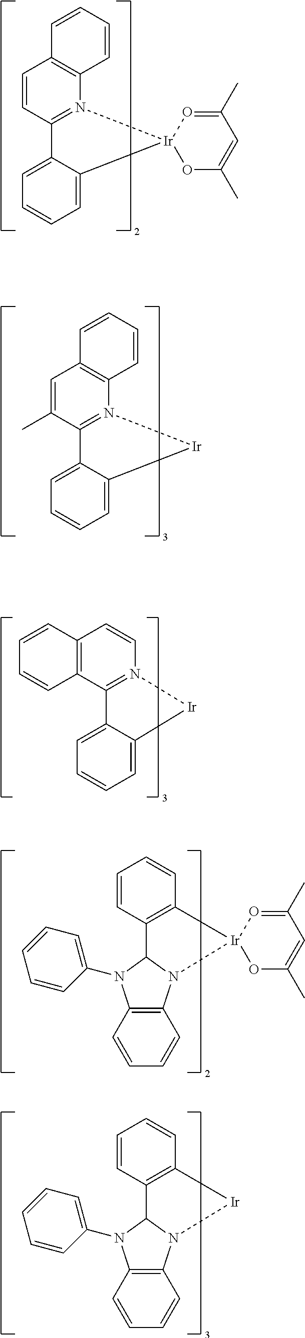

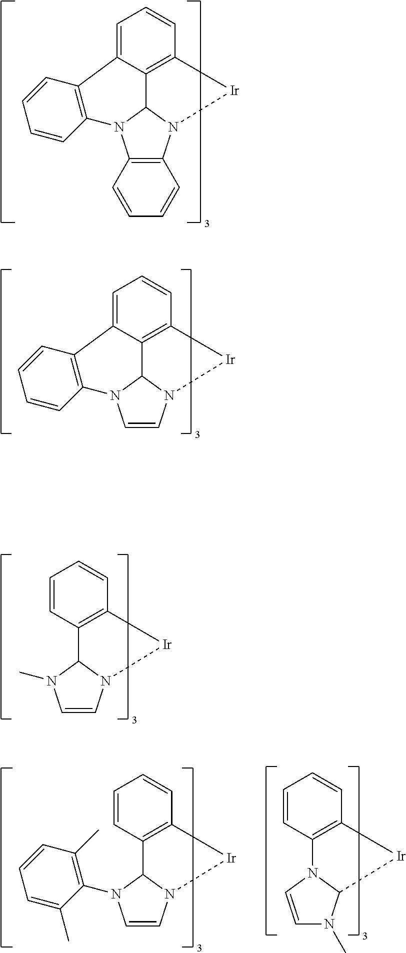

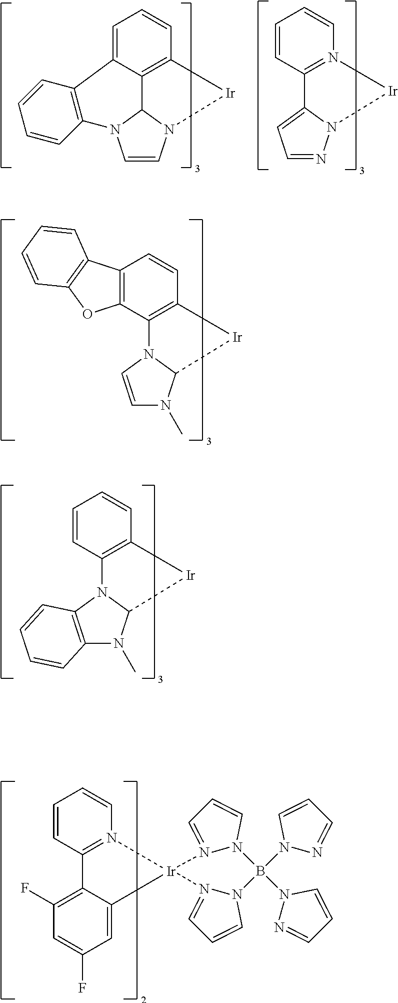

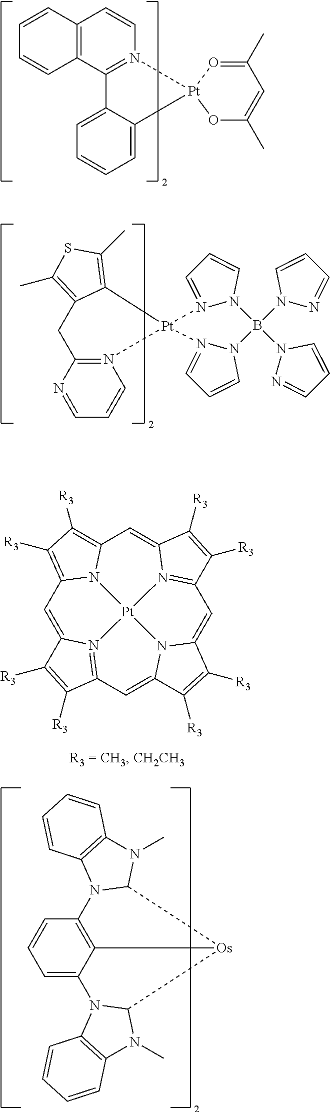

When the fluorescent light-emitting dopant is used, examples of the fluorescent light-emitting dopant include, but not particularly limited to, a benzoxazole derivative, a benzothiazole derivative, a benzimidazole derivative, a styrylbenzene derivative, a polyphenyl derivative, a diphenylbutadiene derivative, a tetraphenylbutadiene derivative, a naphthalimide derivative, a coumarin derivative, a fused aromatic compound, a perinone derivative, an oxadiazole derivative, an oxazine derivative, an aldazine derivative, a pyrrolidine derivative, a cyclopentadiene derivative, a bisstyrylanthracene derivative, a quinacridone derivative, a pyrrolopyridine derivative, a thiadiazolopyridine derivative, a styrylamine derivative, a diketopyrrolopyrrole derivative, an aromatic dimethylidyne compound, various metal complexes typified by a metal complex of an 8-quinolinol derivative, a metal complex of a pyrromethene derivative, a rare earth complex, and a transition metal complex, polymer compounds, such as polythiophene, polyphenylene, and polyphenylene vinylene, and an organic silane derivative. The fluorescent light-emitting dopant is preferably, for example, a fused aromatic derivative, a styryl derivative, a diketopyrrolopyrrole derivative, an oxazine derivative, a pyrromethene metal complex, a transition metal complex, or a lanthanoid complex. The fluorescent light-emitting dopant is more preferably, for example, naphthalene, pyrene, chrysene, triphenylene, benzo[c]phenanthrene, benz[a]anthracene, pentacene, perylene, fluoranthene, acenaphthofluoranthene, dibenz[a,j]anthracene, dibenz[a,h]anthracene, benzo[a]naphthalene, hexacene, naphtho[2,1-f]isoquinoline, α-naphthaphenanthridine, phenanthroxazole, quinolino[6,5-f]quinoline, or benzothiophanthrene. Those compounds may each have an alkyl group, an aryl group, an aromatic heterocyclic group, or a diarylamino group as a substituent. In addition, the content of the fluorescent light-emitting dopant material is preferably from 0.1 wt % to 20 wt %, more preferably from 1 wt % to 10 wt % with respect to the host material.

When the thermally activated delayed fluorescent light-emitting dopant is used, examples of the thermally activated delayed fluorescent light-emitting dopant include, but not particularly limited to, a metal complex, such as a tin complex or a copper complex, an indolocarbazole derivative described in WO 2011/070963 A1, a cyanobenzene derivative described in Nature 2012, 492, 234, a carbazole derivative, a phenazine derivative described in Nature Photonics 2014, 8, 326, an oxadiazole derivative, a triazole derivative, a sulfone derivative, a phenoxazine derivative, and an acridine derivative. In addition, the content of the thermally activated delayed fluorescent light-emitting dopant material is preferably from 0.1% to 90%, more preferably from 1% to 50% with respect to the host material.

—Injecting Layer—

The injecting layer refers to a layer formed between an electrode and an organic layer for the purposes of lowering a driving voltage and improving light emission luminance, and includes a hole-injecting layer and an electron-injecting layer. The injecting layer may be interposed between the anode and the light-emitting layer or the hole-transporting layer, or may be interposed between the cathode and the light-emitting layer or the electron-transporting layer. The injecting layer may be formed as required.

—Hole-Blocking Layer—

The hole-blocking layer has, in a broad sense, the function of an electron-transporting layer, and is formed of a hole-blocking material that has a remarkably small ability to transport holes while having a function of transporting electrons, and hence the hole-blocking layer is capable of improving the probability of recombining an electron and a hole in the light-emitting layer by blocking holes while transporting electrons.

Although the material for an organic electroluminescent device of the present invention may be used in the hole-blocking layer, a known hole-blocking layer material may be used.

—Electron-Blocking Layer—

The electron-blocking layer has, in a broad sense, the function of a hole-transporting layer, and is capable of improving the probability of recombining an electron and a hole in the light-emitting layer by blocking electrons while transporting holes.

Although the material for an organic electroluminescent device of the present invention may be used in the electron-blocking layer, a known electron-blocking layer material may be used, and a material for the hole-transporting layer to be described later may be used as required. The thickness of the electron-blocking layer is preferably from 3 nm to 100 nm, more preferably from 5 nm to 30 nm.

—Exciton-Blocking Layer—

The exciton-blocking layer refers to a layer for blocking excitons produced by the recombination of a hole and an electron in the light-emitting layer from diffusing into charge-transporting layers. The insertion of this layer enables efficient confinement of the excitons in the light-emitting layer, thereby being able to improve the luminous efficiency of the device. In a device in which two or more light-emitting layers are adjacent to each other, the exciton-blocking layer may be inserted between two adjacent light-emitting layers.

A known exciton-blocking layer material may be used as a material for the exciton-blocking layer. Examples thereof include 1,3-dicarbazolylbenzene (mCP) and bis(2-methyl-8-quinolinolato)-4-phenylphenolatoaluminum(III) (BAlq).

—Hole-Transporting Layer—

The hole-transporting layer is formed of a hole-transporting material having a function of transporting holes, and a single hole-transporting layer or a plurality of hole-transporting layers may be formed.

The hole-transporting material has a hole-injecting property or a hole-transporting property or has an electron-blocking property, and any of an organic material and an inorganic material may be used as the hole-transporting material. The material for an organic electroluminescent device of the present invention may be used as the hole-transporting layer, but any compound selected from conventionally known compounds may be used. Examples of the known hole-transporting material include a porphyrin derivative, an arylamine derivative, a triazole derivative, an oxadiazole derivative, an imidazole derivative, a polyarylalkane derivative, a pyrazoline derivative and a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline-based copolymer, and a conductive high-molecular weight oligomer, in particular, a thiophene oligomer. Of those, a porphyrin derivative, an arylamine derivative, and a styrylamine derivative are preferably used, and an arylamine compound is more preferably used.

—Electron-Transporting Layer—

The electron-transporting layer is formed of a material having a function of transporting electrons, and a single electron-transporting layer or a plurality of electron-transporting layers may be formed.

An electron-transporting material (which also serves as a hole-blocking material in some cases) only needs to have a function of transferring electrons injected from the cathode into the light-emitting layer. Any compound selected from conventionally known compounds may be used for the electron-transporting layer. Examples thereof include a polycyclic aromatic derivative, such as naphthalene, anthracene, or phenanthroline, a tris(8-quinolinolato)aluminum(III) derivative, a phosphine oxide derivative, a nitro-substituted fluorene derivative, a diphenylquinone derivative, a thiopyran dioxide derivative, a carbodiimide, a fluorenylidenemethane derivative, anthraquinodimethane and anthrone derivatives, a bipyridine derivative, a quinoline derivative, an oxadiazole derivative, a benzimidazole derivative, a benzothiazole derivative, and an indolocarbazole derivative. Further, it is also possible to use a polymer material in which any of those materials is introduced in a polymer chain or is used as a polymer main chain.

### EXAMPLES

The present invention is described in more detail below by way of Examples. However, the present invention is not limited to Examples below, and may be carried out in various modes as long as the modes do not deviate from the gist thereof.

Measurement of Molecular Weight and Molecular Weight Distribution of Polymer

A GPC (manufactured by Tosoh Corporation, HLC-8120GPC) was used in the measurement of the molecular weight and molecular weight distribution of a synthesized polymer, and the measurement was performed by using tetrahydrofuran (THF) as a solvent at a flow rate of 1.0 ml/min and a column temperature of 40° C. The molecular weight of the polymer was calculated as a molecular weight in terms of polystyrene by using a calibration curve based on a monodisperse polystyrene.

Evaluation of Solubility of Polymer

The solubility of a synthesized polymer was evaluated by the following method. The polymer was mixed with toluene so that its concentration became 0.5 wt %, followed by an ultrasonic treatment at room temperature for 30 min. Further, the resultant solution was left at rest at room temperature for 1 hr, and was then visually observed. The solubility was judged as follows: a case in which no insoluble matter was deposited in the solution was indicated by Symbol “∘”, and a case in which insoluble matter was present in the solution was indicated by Symbol “x”.

An example in which a polymer was synthesized by polycondensation is described below, but the polymerization method is not limited thereto, and any other polymerization method, such as a radical polymerization method or an ionic polymerization method, is also permitted.

### Synthesis Example 1

Polymer A was synthesized via Intermediates A and B, and Polymerization Intermediates A and B.

(Synthesis of Intermediate A)

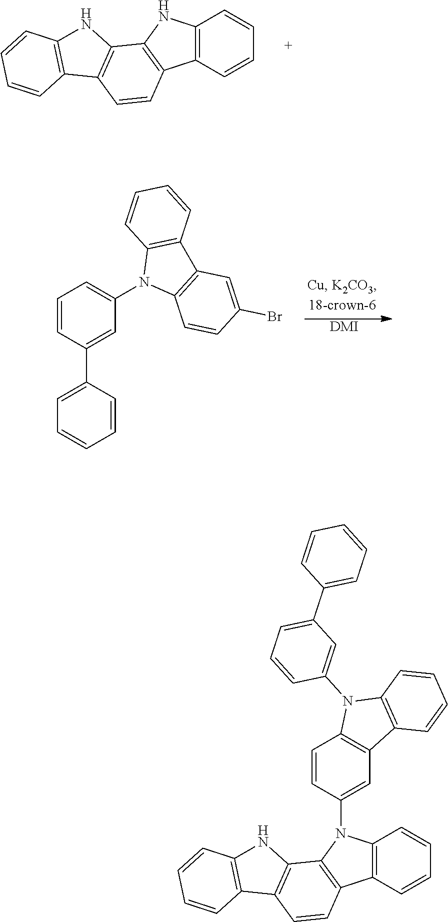

Under a nitrogen atmosphere, 5.13 g (20.0 mmol) of 11,12-dihydroindolo[2,3-a]carbazole, 7.97 g (20.0 mmol) of 9-(3-biphenylyl)-3-bromocarbazole, 6.36 g (100.1 mmol) of copper, 8.30 g (60.0 mmol) of potassium carbonate, 53.0 mg (0.2 mmol) of 18-crown-6, and 60 ml of dimethylimidazolidinone were added and stirred. After that, the mixture was heated to 190° C., and was stirred for 48 hr. The reaction solution was cooled to room temperature, and then copper and inorganic matter were separated by filtration. 200 ml of a mixed solvent containing water and ethanol at 1:1 was added to the filtrate, and the mixture was stirred, followed by the separation of a deposited solid by filtration. The solid was dried under reduced pressure, and was then purified by column chromatography to provide 9.41 g (16.4 mmol, yield: 82.0%) of Intermediate A that was white powder.

(Synthesis of Intermediate B)

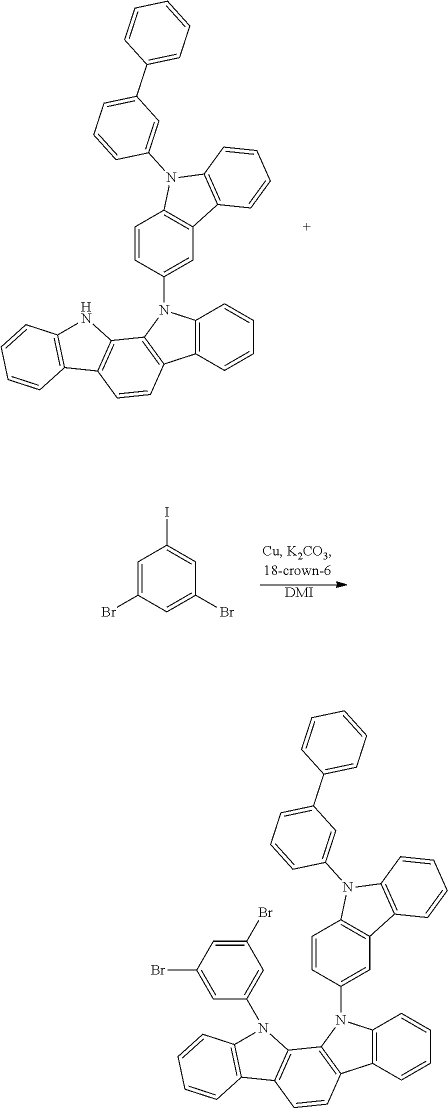

Under a nitrogen atmosphere, 5.74 g (10.0 mmol) of Intermediate A, 3.99 g (10.0 mmol) of 1,3-dibromo-5-iodobenzene, 3.18 g (50.0 mmol) of copper, 4.15 g (30.0 mmol) of potassium carbonate, 264 mg (0.1 mmol) of 18-crown-6, and 60 ml of dimethylimidazolidinone were added and stirred. After that, the mixture was heated to 190° C., and was stirred for 48 hr. The reaction solution was cooled to room temperature, and then copper and inorganic matter were separated by filtration. 200 ml of a mixed solvent containing water and ethanol at 1:1 was added to the filtrate, and the mixture was stirred, followed by the separation of a deposited solid by filtration. The solid was dried under reduced pressure, and was then purified by column chromatography to provide 6.92 g (8.57 mmol, yield: 85.6%) of Intermediate B that was pale yellow powder.

(Synthesis of Polymer A)

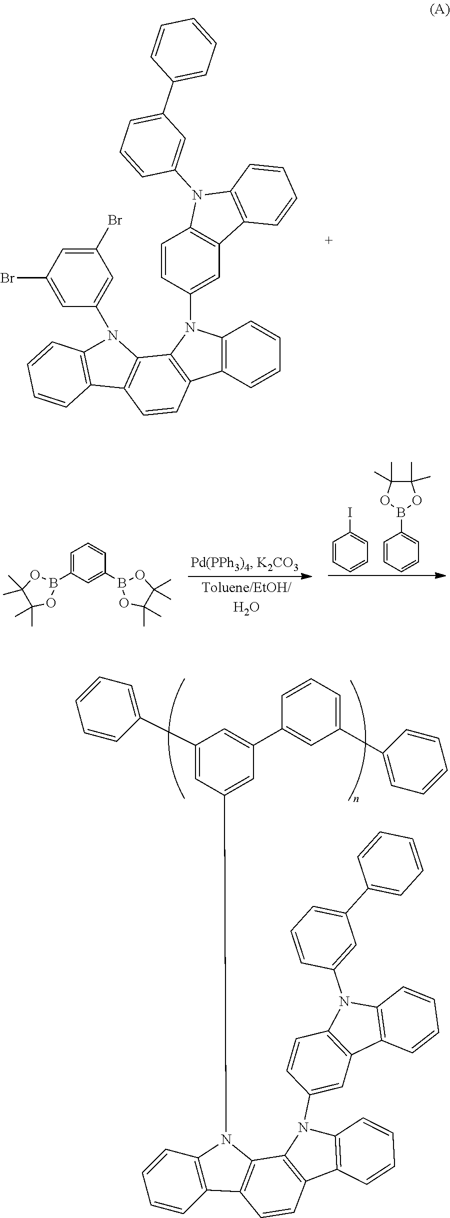

(Procedure 1) 2.0 g (2.5 mmol) of Intermediate B, 0.82 g (2.5 mmol) of 1,3-benzenediboronic acid bis(pinacol) ester, 0.086 g (0.074 mmol) of tetrakistriphenylphosphine palladium, 1.0 g (7.4 mmol) of potassium carbonate, and a mixture of 20 ml of toluene, 10 ml of ethanol, and 10 ml of water were added and stirred. After that, the mixture was heated to 90° C., and was stirred for 12 hr. The reaction solution was cooled to room temperature, and then a precipitate and an organic layer were recovered. A deposit deposited by adding ethanol to the organic layer was recovered together with the precipitate, and the recovered product was purified by column chromatography to provide Polymerization Intermediate A that was pale yellow powder.
(Procedure 2) Polymerization Intermediate B that was pale yellow powder was obtained by performing the same operation through use of Polymerization Intermediate A instead of Intermediate B of the procedure 1 and through use of iodobenzene instead of 1,3-benzenediboronic acid bis(pinacol) ester of the procedure.
(Procedure 3) 1.2 g of Polymer A that was colorless powder was obtained by performing the same operation as that described above through use of Polymerization Intermediate B instead of Intermediate B of the procedure 1 and through use of phenylboronic acid instead of 1,3-benzenediboronic acid bis(pinacol) ester of the procedure. Polymer A thus obtained had a weight-average molecular weight Mw of 7,114, a number-average molecular weight Mn of 3,311, and a ratio Mw/Mn of 2.15.

### Synthesis Example 2

Polymer B was synthesized via Intermediates C and D, Intermediates E and F, and Polymerization Intermediates C and D.

(Synthesis of Intermediate C)

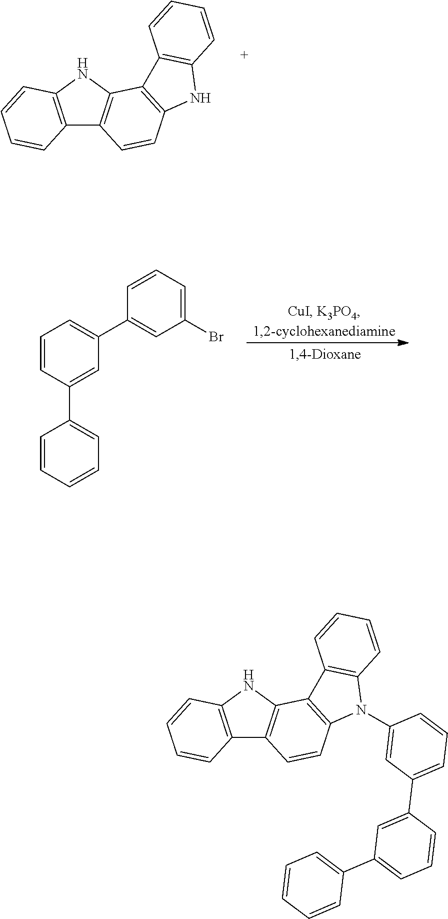 [SMILES: c1ccc2c(c1)[nH]c1c2ccc2[nH]c3ccccc3c21 ; Brc1cccc(-c2cccc(-c3ccccc3)c2)c1 ; c1ccc(-c2cccc(-c3cccc(-n4c5ccccc5c5c6[nH]c7ccccc7c6ccc54)c3)c2)cc1]

Under a nitrogen atmosphere, 5.13 g (20.0 mmol) of 11,12-dihydroindolo[3,2-a]carbazole, 6.19 g (20.0 mmol) of 3-bromo-m-terphenyl, 0.11 g (0.60 mmol) of copper iodide, 21.24 g (100.1 mmol) of tripotassium phosphate, 0.91 g (8.01 mmol) of trans-1,2-cyclohexanediamine, and 100 ml of 1,4-dioxane were added and stirred. After that, the mixture was heated to 130° C., and was stirred for 48 hr. The reaction solution was cooled to room temperature, and then inorganic matter was separated by filtration. The filtrate was dried under reduced pressure, and was then purified by column chromatography to provide 9.10 g (18.8 mmol, yield: 93.8%) of Intermediate C that was white powder.

(Synthesis of Intermediate D)

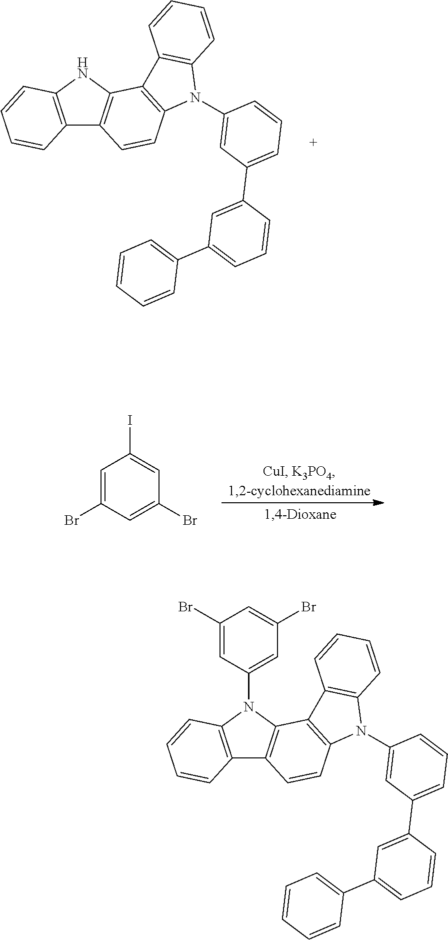 [SMILES: c1ccc(-c2cccc(-c3cccc(-n4c5ccccc5c5c6[nH]c7ccccc7c6ccc54)c3)c2)cc1 ; Brc1cc(Br)cc(I)c1 ; Brc1cc(Br)cc(-n2c3ccccc3c3ccc4c(c5ccccc5n4-c4cccc(-c5cccc(-c6ccccc6)c5)c4)c32)c1]

Under a nitrogen atmosphere, 4.85 g (10.0 mmol) of Intermediate C, 3.62 g (10.0 mmol) of 1,3-dibromo-5-iodobenzene, 0.057 g (0.30 mmol) of copper iodide, 10.62 g (50.04 mmol) of tripotassium phosphate, 0.46 g (4.00 mmol) of trans-1,2-cyclohexanediamine, and 50 ml of 1,4-dioxane were added and stirred. After that, the mixture was heated to 130° C., and was stirred for 72 hr. The reaction solution was cooled to room temperature, and then inorganic matter was separated by filtration. The filtrate was dried under reduced pressure, and was then purified by column chromatography to provide 6.23 g (8.67 mmol, yield: 86.6%) of Intermediate D that was pale yellow powder.

(Synthesis of Intermediate E)

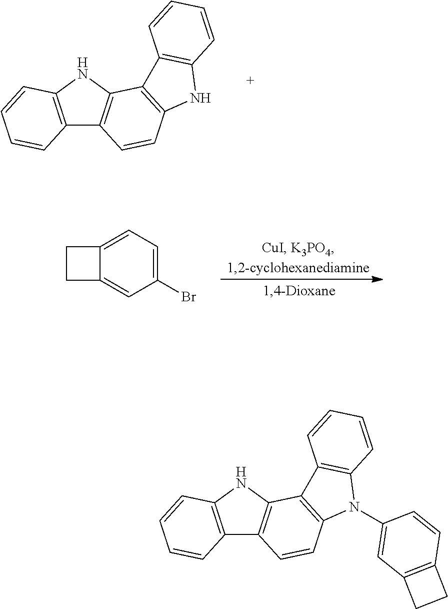 [SMILES: c1ccc2c(c1)[nH]c1c2ccc2[nH]c3ccccc3c21 ; Brc1ccc2c(c1)CC2 ; c1ccc2c(c1)[nH]c1c2ccc2c1c1ccccc1n2-c1ccc2c(c1)CC2]

Under a nitrogen atmosphere, 2.57 g (10.0 mmol) of 11,12-dihydroindolo[3,2-a]carbazole, 1.83 g (10.0 mmol) of 4-bromobenzocyclobutene, 0.057 g (0.30 mmol) of copper iodide, 10.64 g (50.13 mmol) of tripotassium phosphate, 0.46 g (4.00 mmol) of trans-1,2-cyclohexanediamine, and 50 ml of 1,4-dioxane were added and stirred. After that, the mixture was heated to 130° C., and was stirred for 48 hr. The reaction solution was cooled to room temperature, and then inorganic matter was separated by filtration. The filtrate was dried under reduced pressure, and was then purified by column chromatography to provide 3.22 g (8.98 mmol, yield: 89.6%) of Intermediate E that was white powder.

(Synthesis of Intermediate F)

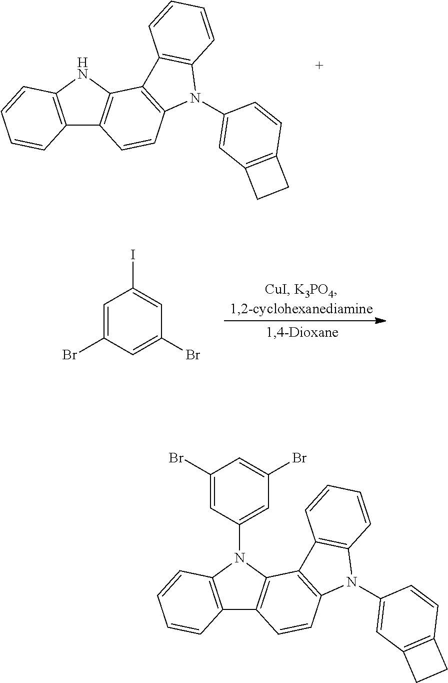 [SMILES: c1ccc2c(c1)[nH]c1c2ccc2c1c1ccccc1n2-c1ccc2c(c1)CC2 ; Brc1cc(Br)cc(I)c1 ; Brc1cc(Br)cc(-n2c3ccccc3c3ccc4c(c5ccccc5n4-c4ccc5c(c4)CC5)c32)c1]

Under a nitrogen atmosphere, 1.8 g (5.0 mmol) of Intermediate E, 1.82 g (5.0 mmol) of 1,3-dibromo-5-iodobenzene, 0.029 g (0.15 mmol) of copper iodide, 5.33 g (25.11 mmol) of tripotassium phosphate, 0.22 g (2.01 mmol) of trans-1,2-cyclohexanediamine, and 20 ml of 1,4-dioxane were added and stirred. After that, the mixture was heated to 130° C., and was stirred for 72 hr. The reaction solution was cooled to room temperature, and then inorganic matter was separated by filtration. The filtrate was dried under reduced pressure, and was then purified by column chromatography to provide 2.29 g (3.87 mmol, yield: 77.0%) of Intermediate F that was pale yellow powder.

(Synthesis of Polymer B)

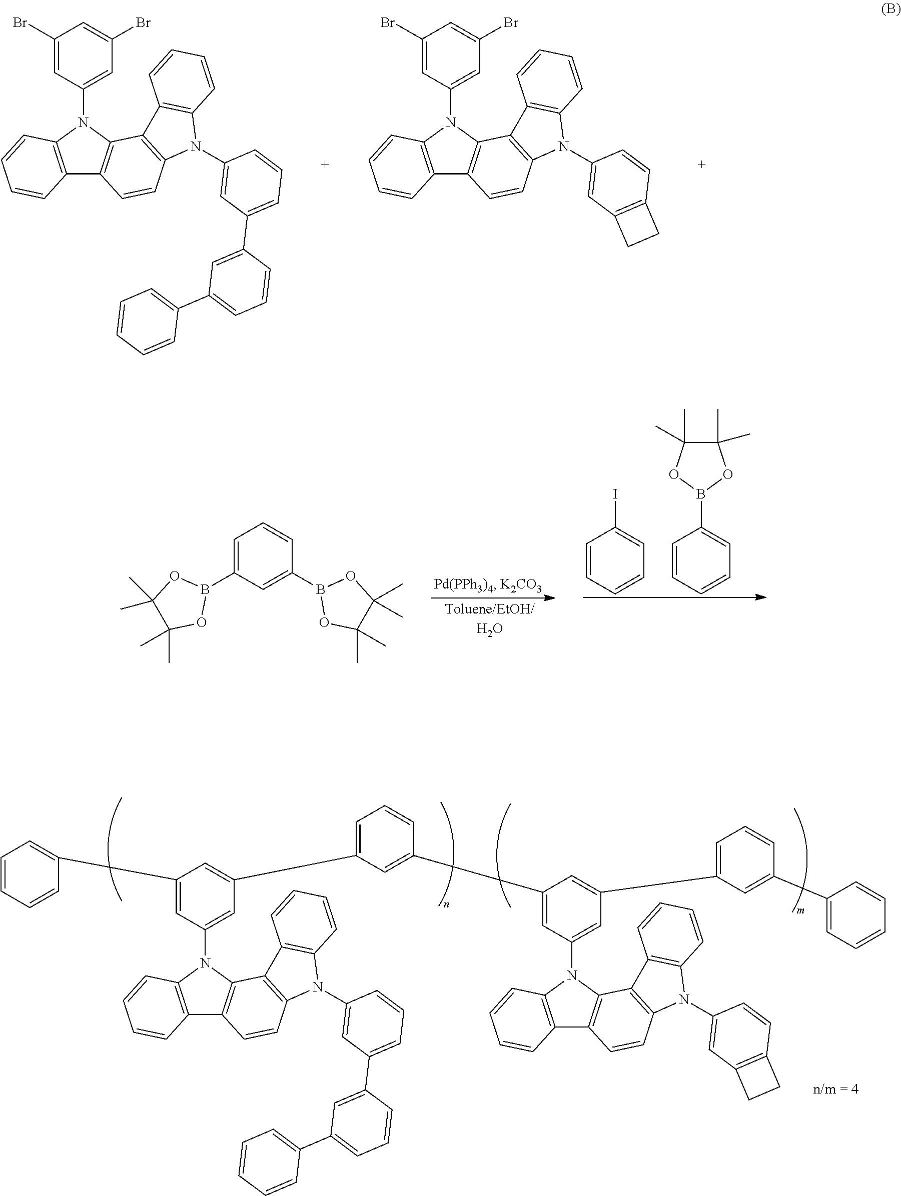

(Procedure 1) 2.87 g (4.0 mmol) of Intermediate D, 0.59 g (1.0 mmol) of Intermediate F, 1.65 g (5.0 mmol) of 1,3-benzenediboronic acid bis (pinacol) ester, 0.17 g (0.15 mmol) of tetrakistriphenylphosphine palladium, 2.07 g (15.0 mmol) of potassium carbonate, and a mixture of 30 ml of toluene, 15 ml of ethanol, and 15 ml of water were added and stirred. After that, the mixture was heated to 90° C., and was stirred for 12 hr. The reaction solution was cooled to room temperature, and then a precipitate and an organic layer were recovered. A deposit deposited by adding ethanol to the organic layer was recovered together with the precipitate, and the recovered product was purified by column chromatography to provide Polymerization Intermediate C that was pale yellow powder.
(Procedure 2) Polymerization Intermediate D that was pale yellow powder was obtained by performing the same operation through use of Polymerization Intermediate C instead of Intermediate D and Intermediate F of the procedure 1 and through use of iodobenzene instead of 1,3-benzenediboronic acid bis (pinacol) ester of the procedure.
(Procedure 3) 2.3 g of Polymer B that was colorless powder was obtained by performing the same operation as that described above through use of Polymerization Intermediate D instead of Polymerization Intermediate C of the procedure 2 and through use of phenylboronic acid instead of iodobenzene of the procedure. Polymer B thus obtained had a weight-average molecular weight Mw of 14,372, a number-average molecular weight Mn of 4,996, and a ratio Mw/Mn of 2.88.

### Synthesis Examples 3 to 12

The results of the GPC measurement of the polymers synthesized by synthesis approaches similar to those described above, and the results of the solubility evaluations of the polymers are shown in Table 1.

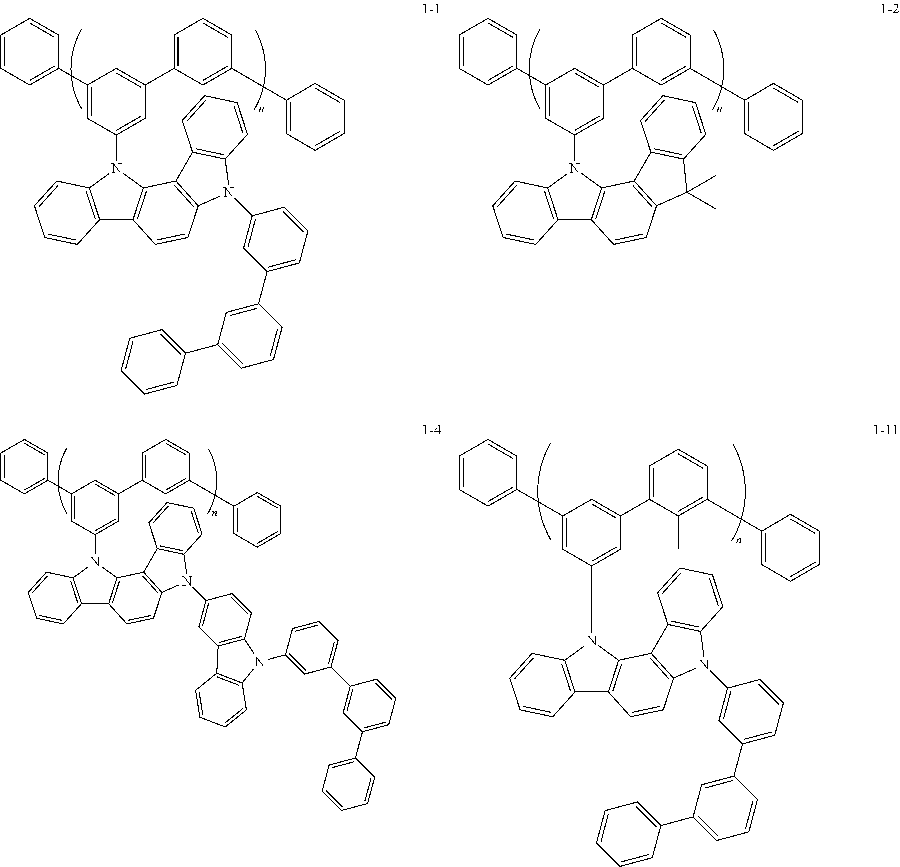

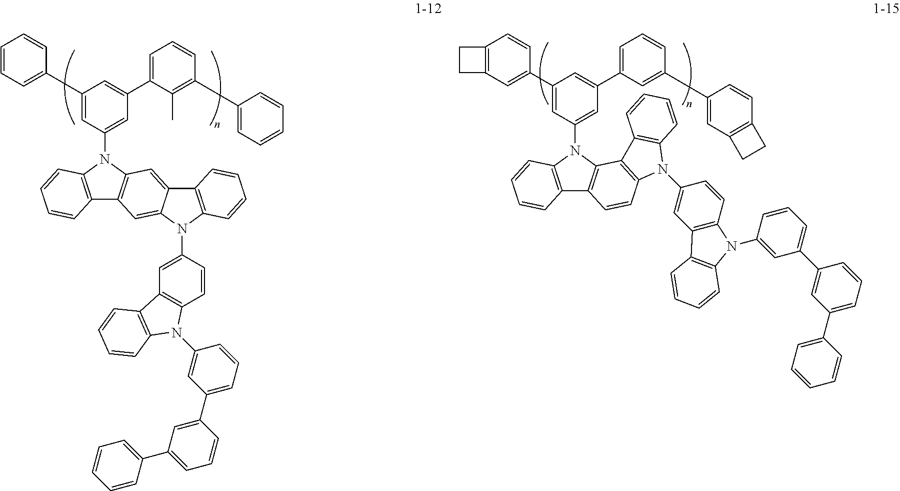

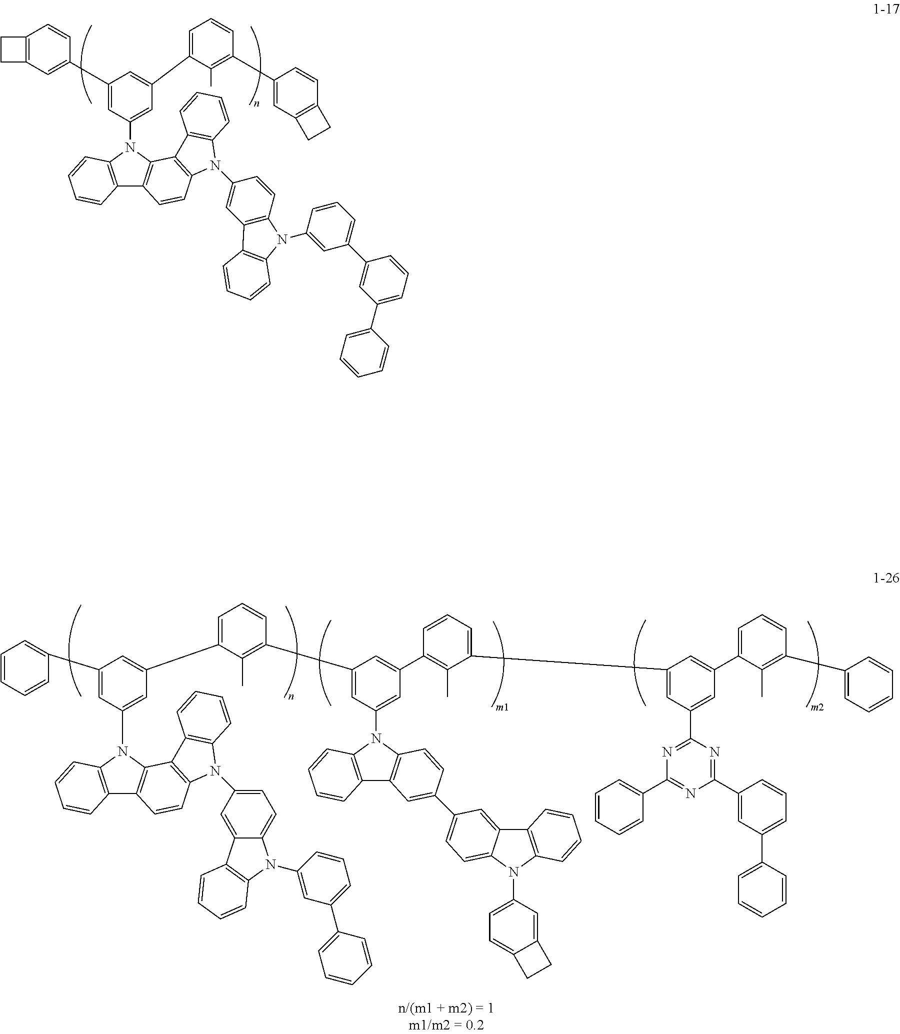

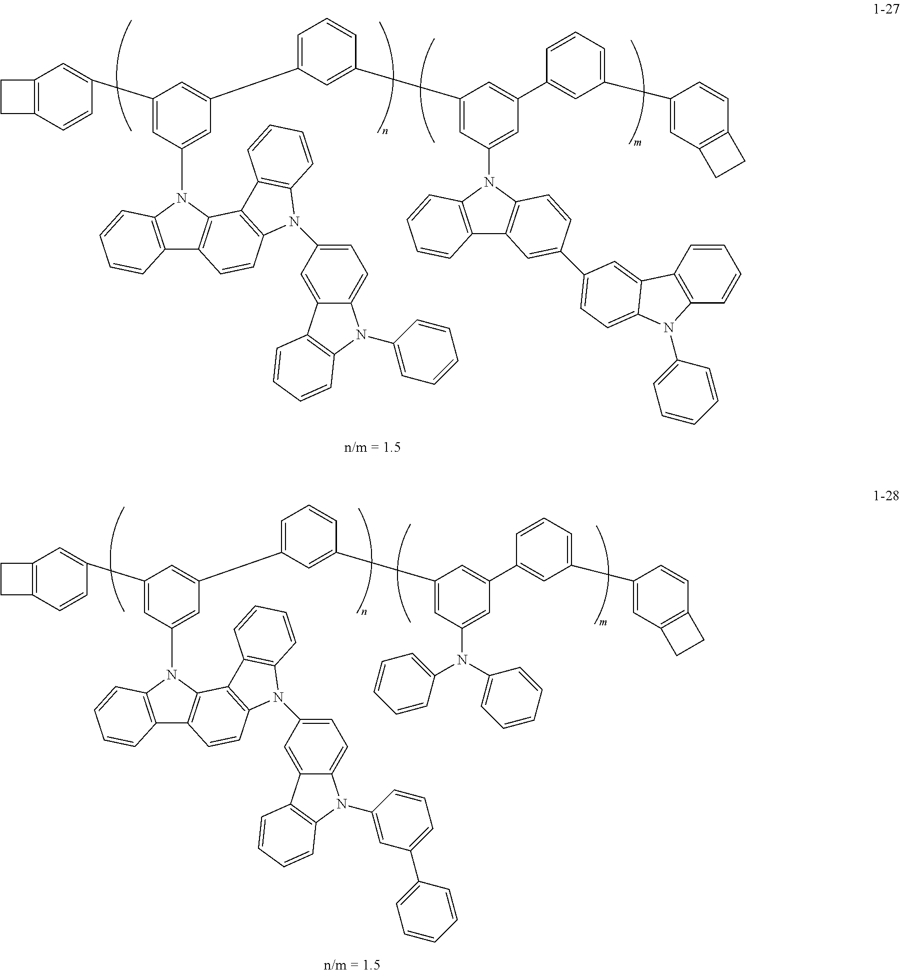

TABLE 1

| Synthesis | | | | | |
|---|---|---|---|---|---|
| Example | Polymer | Mw | Mn | Mw/Mn | Solubility |
| 1 | A | 7,114 | 3,311 | 2.15 | ◯ |
| 2 | B | 14,372 | 4,996 | 2.88 | ◯ |
| 3 | 1-1 | 12,610 | 4,723 | 2.67 | ◯ |
| 4 | 1-2 | 6,531 | 3,018 | 2.16 | ◯ |
| 5 | 1-4 | 9,805 | 4,221 | 2.32 | ◯ |
| 6 | 1-11 | 18,898 | 5,253 | 3.60 | ◯ |
| 7 | 1-12 | 8,351 | 4,320 | 1.93 | ◯ |
| 8 | 1-15 | 10,566 | 4,501 | 2.35 | ◯ |
| 9 | 1-17 | 10,119 | 4,492 | 2.25 | ◯ |
| 10 | 1-26 | 15,787 | 5,841 | 2.70 | ◯ |
| 11 | 1-27 | 11,285 | 3,097 | 3.64 | ◯ |
| 12 | 1-28 | 8,541 | 3,887 | 2.20 | ◯ |

Polymer numbers and compound numbers described in Examples and Comparative Examples correspond to numbers given to the foregoing exemplified polymers and numbers given to the following compounds.

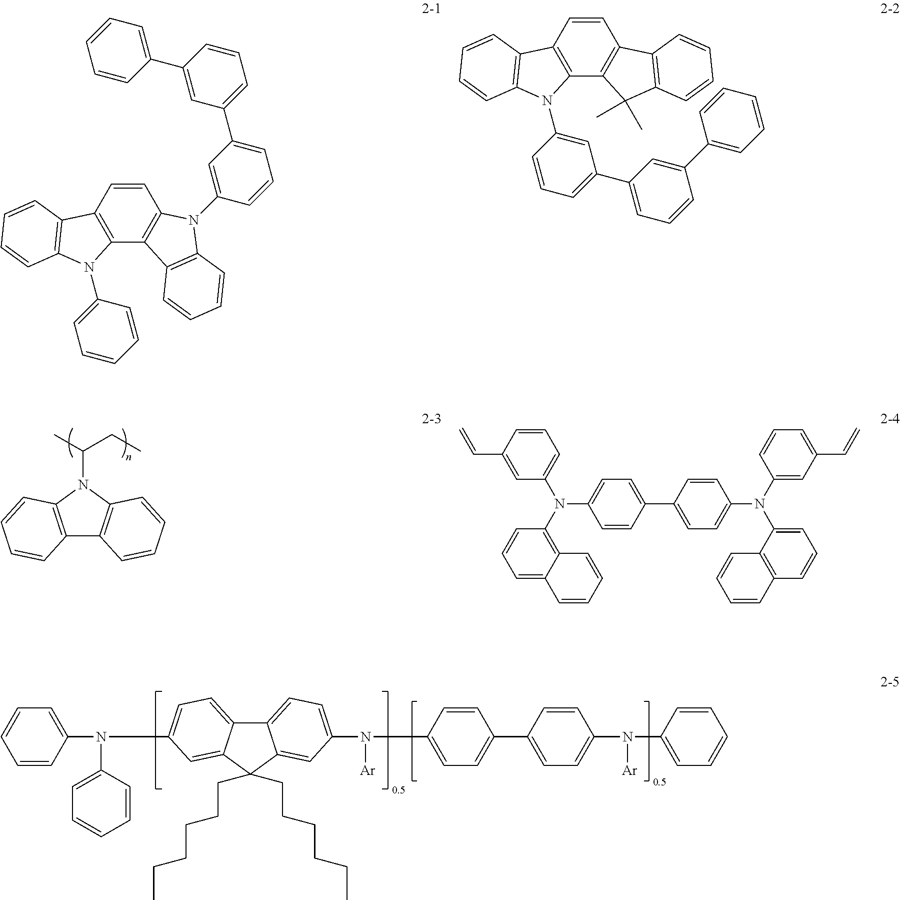

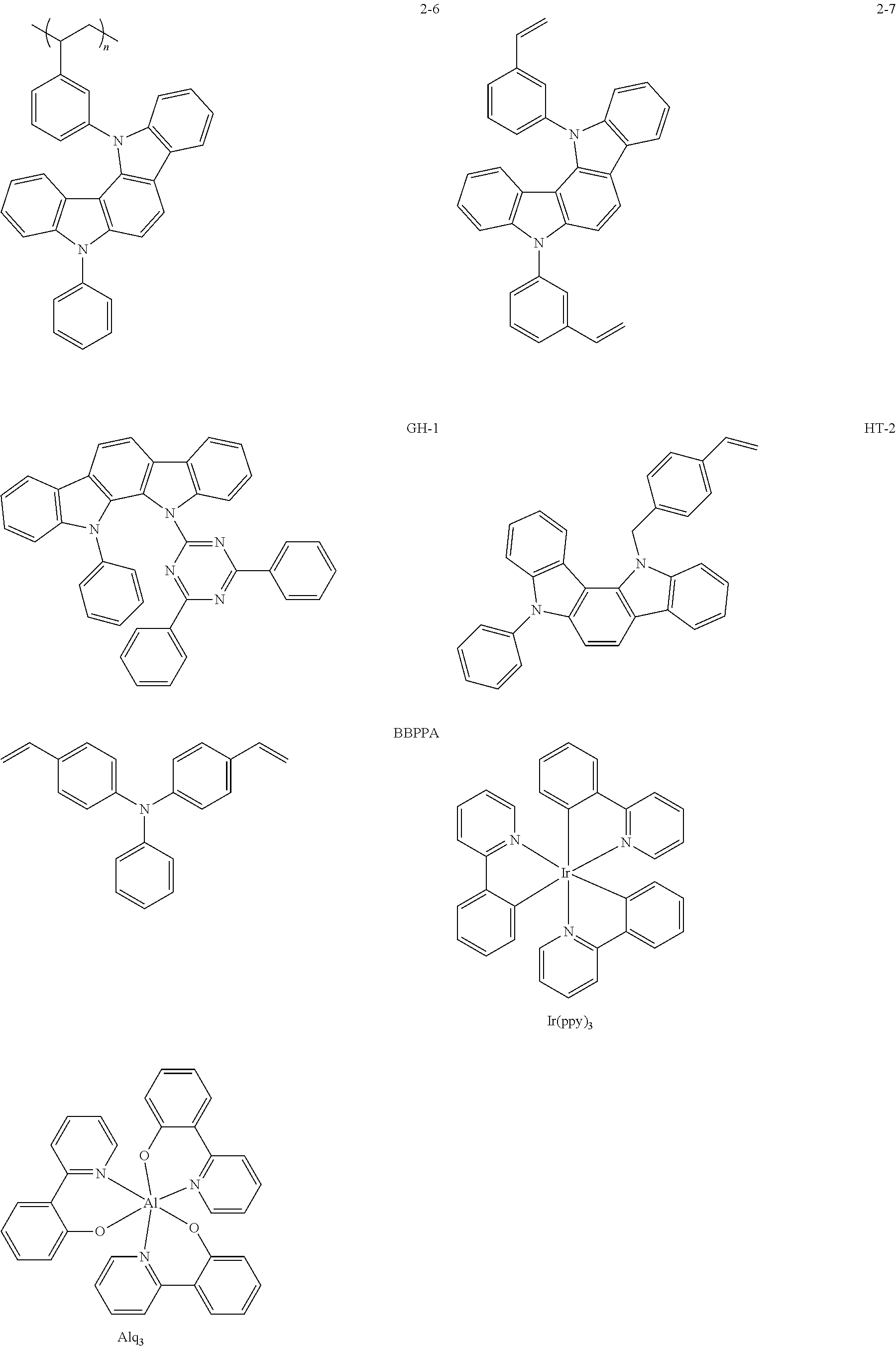

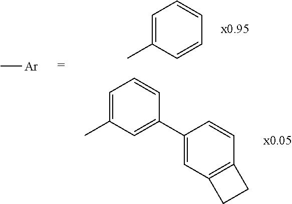

### Examples 1 and 2, and Comparative Examples 1 and 2

Optical evaluations were performed by using Polymers 1-1 and 1-2, and Compounds 2-1 and 2-2 for comparison. An energy gap Eg_{77K} was determined by the following method. Each of the polymers and the compounds was dissolved in a solvent (test concentration: 10⁻⁵ [mol/l], solvent: 2-methyltetrahydrofuran) to provide a sample for phosphorescence measurement. The sample for phosphorescence measurement loaded into a quartz cell was cooled to 77 [K], and the sample for phosphorescence measurement was irradiated with excitation light, followed by the measurement of the phosphorescence intensity of the sample while the wavelength of the light was changed. In the phosphorescence spectrum of the sample, an axis of ordinate indicated the phosphorescence intensity, and an axis of abscissa indicated the wavelength. A tangent was drawn to the rise-up of the phosphorescence spectrum at shorter wavelengths, and a wavelength value λedge [nm] of the point of intersection of the tangent and the axis of abscissa was determined. A value obtained by converting the wavelength value into an energy value through use of the following conversion equation was adopted as the Eg_{77K}.

Eg_{77K}[eV]=1,239.85/λedge Conversion equation:

A small fluorescence lifetime-measuring apparatus C11367 manufactured by Hamamatsu Photonics K.K. and its phosphorescence option equipment were used in the phosphorescence measurement. The polymers and compounds whose Eg_{77K}s were measured are Polymers 1-1 and 1-2, and Compounds 2-1 and 2-2. The results of the measurement of the Eg_{77K}s of the respective compounds are shown in Table 2. In addition, the phosphorescence spectrum of Example 1 is shown in FIG. 2.

TABLE 2

| | Polymer | Eg_{77K} |
|---|---|---|
| | (compound) | [eV] |
| Example 1 | 1-1 | 2.89 |
| Example 2 | 1-2 | 2.70 |
| Comparative Example 1 | 2-1 | 2.90 |
| Comparative Example 2 | 2-2 | 2.71 |

It was confirmed from the foregoing results that the polymer of the present invention had a triplet excitation energy comparable to that of a low-molecular weight material that was its repeating unit.

### Example 3

Device characteristics were evaluated by using Polymer 1-4 in a hole-transporting layer.

Poly(3,4-ethylenedioxythiophene)/polystyrenesulfonic acid (PEDOT/PSS) (manufactured by H.C. Starck, product name: CLEVIOS PCH8000) was formed into a hole-injecting layer having a thickness of 25 nm on a glass substrate with ITO having a thickness of 150 nm, which had been subjected to solvent washing and a UV ozone treatment. Next, Polymer 1-4 was dissolved in toluene to prepare a 0.4 wt % solution, and the solution was formed into the hole-transporting layer having a thickness of 20 nm by a spin coating method. Then, GH-1 serving as a host and Ir(ppy)₃ serving as a light-emitting dopant were co-deposited from deposition sources different from each other to form a light-emitting layer having a thickness of 40 nm. At this time, the co-deposition was performed under such a deposition condition that the concentration of Ir (ppy)₃ became 5 wt %. After that, Alq₃ was formed into a film having a thickness of 35 nm, and LiF/Al was formed into a cathode having a thickness of 170 nm by using a vacuum deposition apparatus. The device was sealed in a glove box to produce an organic electroluminescent device.

### Examples 4 and 5

Organic EL devices were produced in the same manner as in Example 3 except that in Example 3, Polymer 1-12 or 1-28 was used as the hole-transporting layer.

### Comparative Example 3

An organic EL device was produced in the same manner as in Example 3 except that in Example 3, spin coating film formation was performed by using Compound 2-4 as the hole-transporting layer, and then photopolymerization was performed by irradiating the layer with UV light for 90 sec through use of a UV irradiation apparatus of an AC power source system.

### Comparative Example 4

An organic EL device was produced in the same manner as in Example 3 except that in Example 3, spin coating film formation was performed by using Compound 2-5 as the hole-transporting layer, and then the layer was heated and cured with a hot plate under an anaerobic condition at 230° C. for 1 hr.

When an external power source was connected to each of the organic EL devices produced in Examples 3 to 5, and Comparative Examples 3 and 4 to apply a DC voltage to the device, an emission spectrum having a local maximum wavelength of 530 nm was observed, and hence it was found that light emission from Ir(ppy)₃ was obtained.

The luminances of the produced organic EL devices are shown in Table 3. The luminances in Table 3 are values at a driving current of 20 mA/cm². The luminances are shown as relative values when the luminance of Comparative Example 3 is set to 100%.

TABLE 3

| | Hole-transporting | Luminance |
|---|---|---|
| | layer | (cd/m²) |
| Example 3 | 1-4 | 1,115% |
| Example 4 | 1-12 | 1,068% |
| Example 5 | 1-28 | 1,127% |
| Comparative Example 3 | 2-4 | 96% |
| Comparative Example 4 | 2-5 | 1,020 |

It was confirmed that as compared to an aromatic amine polymer generally used as a hole-transporting material, the polymer of the present invention had an ability to sufficiently confine an exciton excited in a light-emitting layer when used as a hole-transporting layer.

### Example 6

Poly(3,4-ethylenedioxythiophene)/polystyrene sulfonic acid (PEDOT/PSS) (manufactured by H.C. Starck, product name: CLEVIOS PCH8000) was formed into a hole-injecting layer having a thickness of 25 nm on a glass substrate with ITO having a thickness of 150 nm, which had been subjected to solvent washing and a UV ozone treatment. Next, a mixture obtained by mixing HT-2 and BBPPA at a ratio of 5:5 (molar ratio) was dissolved in toluene to prepare a 0.4 wt % solution, and the solution was formed into a film having a thickness of 10 nm by a spin coating method. In addition, the film was heated and cured with a hot plate under an anaerobic condition at 150° C. for 1 hr. The thermally cured film is a film having a crosslinked structure, and is insoluble in a solvent. The thermally cured film is a hole-transporting layer (HTL). Next, Polymer 1-4 was dissolved in toluene to prepare a 0.4 wt % solution, and the solution was formed into an electron-blocking layer (EBL) having a thickness of 10 nm by the spin coating method. Then, GH-1 serving as a host and Ir(ppy)₃ serving as a light-emitting dopant were co-deposited from deposition sources different from each other to form a light-emitting layer having a thickness of 40 nm. At this time, the co-deposition was performed under such a deposition condition that the concentration of Ir(ppy)₃ became 5 wt %. After that, Alq₃ was formed into a film having a thickness of 35 nm, and LiF/Al was formed into a cathode having a thickness of 170 nm by using a vacuum deposition apparatus. The device was sealed in a glove box to produce an organic electroluminescent device.

### Examples 7 and 8

Organic EL devices were each produced in the same manner as in Example 6 except that in Example 6, Polymer 1-11 or 1-27 was used as the electron-blocking layer.

### Comparative Example 5

An organic EL device was produced in the same manner as in Example 6 except that in Example 6, a hole-transporting layer having a thickness of 20 nm was formed by using Compound 2-3 [poly(9-vinylcarbazole), number-average molecular weight: from 25,000 to 50,000], and the electron-blocking layer was not formed.

### Comparative Example 6

An organic EL device was produced in the same manner as in Example 6 except that in Example 6, Compound 2-6 was used as the electron-blocking layer.

When an external power source was connected to each of the organic EL devices produced in Examples 6 to 8, and Comparative Examples 5 and 6 to apply a DC voltage to the device, an emission spectrum having a local maximum wavelength of 530 nm was observed, and hence it was found that light emission from Ir (ppy)₃ was obtained.

The luminances and luminance half-lives of the produced organic EL devices are shown in Table 4. The luminances in Table 4 are values at a driving current of 20 mA/cm², and are initial characteristics. LT90s in Table 4 are each a time period required for a luminance to attenuate from an initial luminance of 9,000 cd/m² to 90% of the initial luminance, and are lifetime characteristics. Each of the characteristics is shown as a relative value when the characteristic of Comparative Example 5 is set to 100%.

TABLE 4

| | Hole- | Electron- | Method of forming | | LT90 at |
|---|---|---|---|---|---|
| | transporting | blocking | light-emitting | Luminance | 9,000 nits |
| | layer | layer | layer | (cd/m²) | (hr) |
| Example 6 | HT-2:BBPPA | 1-4 | Deposition | 99% | 123% |
| Example 7 | HT-2:BBPPA | 1-11 | Deposition | 104% | 118% |
| Example 8 | HT-2:BBPPA | 1-27 | Deposition | 105% | 120% |
| Comparative | 2-3 | — | Deposition | 11,251 | 341 |
| Example 5 | | | | | |
| Comparative | HT-2:BBPPA | 2-6 | Deposition | 101% | 103% |
| Example 6 | | | | | |

### Example 9

Poly(3,4-ethylenedioxythiophene)/polystyrene sulfonic acid (PEDOT/PSS) (manufactured by H.C. Starck, product name: CLEVIOS PCH8000) was formed into a hole-injecting layer having a thickness of 25 nm on a glass substrate with ITO having a thickness of 150 nm, which had been subjected to solvent washing and a UV ozone treatment. Next, a mixture obtained by mixing HT-2 and BBPPA at a ratio of 5:5 (molar ratio) was dissolved in toluene to prepare a 0.4 wt % solution, and the solution was formed into a film having a thickness of 10 nm by a spin coating method. In addition, the film was heated and cured with a hot plate under an anaerobic condition at 150° C. for 1 hr. The thermally cured film is a film having a crosslinked structure, and is insoluble in a solvent. The thermally cured film is a hole-transporting layer (HTL). Next, Polymer 1-15 was dissolved in toluene to prepare a 0.4 wt % solution, and the solution was formed into a film having a thickness of 10 nm by the spin coating method. In addition, the film was heated with a hot plate under an anaerobic condition at 230° C. for 1 hr. The film is an electron-blocking layer (EBL), and is insoluble in a solvent. Then, a toluene solution (1.0 wt %) was prepared by using GH-1 as a host and Ir(ppy)₃ as a light-emitting dopant so that a ratio “host:dopant” became 95:5 (weight ratio), followed by the formation of the solution into a light-emitting layer having a thickness of 40 nm by the spin coating method. After that, Alq₃ was formed into a film having a thickness of 35 nm, and LiF/Al was formed into a cathode having a thickness of 170 nm by using a vacuum deposition apparatus. The device was sealed in a glove box to produce an organic electroluminescent device.

### Examples 10 and 11

Organic EL devices were each produced in the same manner as in Example 9 except that in Example 9, Polymer 1-16 or 1-17 was used as the electron-blocking layer.

### Comparative Example 7

An organic EL device was produced in the same manner as in Example 9 except that in Example 9, a hole-transporting layer having a thickness of 20 nm was formed, and the electron-blocking layer was not formed.

### Comparative Example 8

An organic EL device was produced in the same manner as in Example 9 except that in Example 9, spin coating film formation was performed by using Compound 2-7 as the electron-blocking layer, and then the layer was heated and cured with a hot plate under an anaerobic condition at 150° C. for 1 hr.

When an external power source was connected to each of the organic EL devices produced in Examples 9 to 11, and Comparative Examples 7 and 8 to apply a DC voltage to the device, an emission spectrum having a local maximum wavelength of 530 nm was observed, and hence it was found that light emission from Ir (ppy)₃ was obtained.

The luminances and luminance half-lives of the produced organic EL devices are shown in Table 5. The luminances in Table 5 are values at a driving current of 20 mA/cm², and are initial characteristics. LT90s in Table 5 are each a time period required for a luminance to attenuate from an initial luminance of 9,000 cd/m² to 90% of the initial luminance, and are lifetime characteristics. Each of the characteristics is shown as a relative value when the characteristic of Comparative Example 7 is set to 100%.

TABLE 5

| | Hole- | Electron- | Method of forming | | LT90 at |
|---|---|---|---|---|---|
| | transporting | blocking | light-emitting | Luminance | 9,000 nits |
| | layer | layer | layer | (cd/m²) | (hr) |
| Example 9 | HT-2:BBPPA | 1-15 | Application | 101% | 121% |
| Example 10 | HT-2:BBPPA | 1-16 | Application | 98% | 122% |
| Example 11 | HT-2:BBPPA | 1-17 | Application | 104% | 119% |
| Comparative | HT-2:BBPPA | — | Application | 11,361 | 338 |
| Example 7 | | | | | |
| Comparative | HT-2:BBPPA | 2-7 | Application | 101% | 102% |
| Example 8 | | | | | |

### Example 12

Poly(3,4-ethylenedioxythiophene)/polystyrene sulfonic acid (PEDOT/PSS) (manufactured by H.C. Starck, product name: CLEVIOS PCH8000) was formed into a hole-injecting layer having a thickness of 25 nm on a glass substrate with ITO having a thickness of 150 nm, which had been subjected to solvent washing and a UV ozone treatment. Next, a mixture obtained by mixing HT-2 and BBPPA at a ratio of 5:5 (molar ratio) was dissolved in toluene to prepare a 0.4 wt % solution, and the solution was formed into a film having a thickness of 10 nm by a spin coating method. In addition, the film was heated and cured with a hot plate under an anaerobic condition at 150° C. for 1 hr. The thermally cured film is a film having a crosslinked structure, and is insoluble in a solvent. The thermally cured film is a hole-transporting layer (HTL). Next, Polymer 1-15 was dissolved in toluene to prepare a 0.4 wt % solution, and the solution was formed into a film having a thickness of 10 nm by the spin coating method. In addition, the film was heated with a hot plate under an anaerobic condition at 230° C. for 1 hr so that its solvent was removed. The heated layer is an electron-blocking layer (EBL), and is insoluble in a solvent. Then, a toluene solution (1.0 wt %) was prepared by using Polymer 1-15 as a first host, GH-1 as a second host, and Ir(ppy)₃ as a light-emitting dopant so that a weight ratio between the first host and the second host became 40:60, and a weight ratio “hosts:dopant” became 95:5, followed by the formation of the solution into a light-emitting layer having a thickness of 40 nm by the spin coating method. After that, Alq₃ was formed into a film having a thickness of 35 nm, and LiF/Al was formed into a cathode having a thickness of 170 nm by using a vacuum deposition apparatus. The device was sealed in a glove box to produce an organic electroluminescent device.

### Examples 13 to 15 and Comparative Example 9

Organic EL devices were each produced in the same manner as in Example 12 except that in Example 12, Polymer B, 1-17, 1-26, or 2-6 was used as the first host.

When an external power source was connected to each of the organic EL devices produced in Examples 12 to 15 and Comparative Example 9 to apply a DC voltage to the device, an emission spectrum having a local maximum wavelength of 530 nm was observed, and hence it was found that light emission from Ir(ppy)₃ was obtained.

The luminances and luminance half-lives of the produced organic EL devices are shown in Table 6. The luminances in Table 6 are values at a driving current of 20 mA/cm², and are initial characteristics. LT90s in Table 6 are each a time period required for a luminance to attenuate from an initial luminance of 9,000 cd/m² to 90% of the initial luminance, and are lifetime characteristics. Each of the characteristics is shown as a relative value when the characteristic of Comparative Example 9 is set to 100%.

TABLE 6

| | First host | Second host | Luminance | LT90 at |
|---|---|---|---|---|
| | compound | compound | (cd/m²) | 9,000 nits (hr) |
| Example 12 | 1-15 | GH-1 | 98% | 281% |
| Example 13 | B | GH-1 | 96% | 285% |
| Example 14 | 1-17 | GH-1 | 105% | 282% |
| Example 15 | 1-26 | GH-1 | 104% | 290% |
| Comparative | 2-6 | GH-1 | 9,345 | 191 |
| Example 9 | | | | |

As can be seen from the foregoing results, when the polymer of the present invention is used as an organic EL material, its application, lamination, and film formation can be performed, and both of a satisfactory luminance characteristic and a satisfactory lifetime characteristic can be achieved.

### INDUSTRIAL APPLICABILITY

The polymer for an organic electroluminescent device of the present invention has the polyphenylene chain in its main chain, and has the fused heterocyclic structure in a side chain thereof. Accordingly, the polymer serves as a material for an organic electroluminescent device having a high charge-transporting characteristic, having high stability in an active state of oxidation, reduction, or excitation, and having high heat resistance. An organic electroluminescent device using an organic thin film formed from the polymer shows high luminous efficiency and high driving stability. When the polymer for an organic electroluminescent device of the present invention is used in film formation, the charge-transporting property in the organic layer, and the carrier balance between a hole and an electron therein are adjusted, and hence an organic EL device having higher performance can be achieved.

### REFERENCE SIGNS LIST

1: substrate
2: anode
3: hole-injecting layer
4: hole-transporting layer
5: electron-blocking layer
6: light-emitting layer
7: hole-blocking layer
8: electron-transporting layer
9: electron-injecting layer
10: cathode

1.-9. (canceled)

10. A polymer for an organic electroluminescent device, comprising:
a main chain formed only of a polyphenylene structure; and
a structural unit represented by the following general formula (1) as a repeating unit,
wherein the structural units each represented by the general formula (1) may be the same or different from repeating unit to repeating unit, and
wherein the polymer has a weight-average molecular weight of 1,000 or more and 500,000 or less: 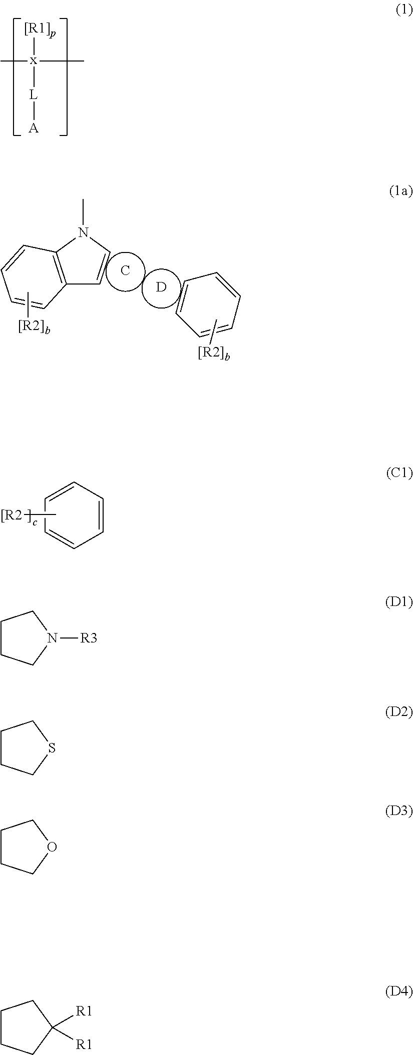
in the general formula (1),
“x” represents a phenylene group bonded at an arbitrary position, or a linked phenylene group obtained by linking the 2 to 6 phenylene groups at arbitrary positions,
A represents a fused aromatic ring group represented by the formula (1a),
a ring C represents an aromatic ring represented by the formula (C1), which is fused with two adjacent rings at arbitrary positions,
a ring D represents a five-membered ring represented by the formula (D1), (D2), (D3), or (D4), which is fused with two adjacent rings at arbitrary positions,
L represents a single bond, a substituted or unsubstituted aromatic hydrocarbon group having 6 to 24 carbon atoms, a substituted or unsubstituted aromatic heterocyclic group having 3 to 21 carbon atoms, or a linked aromatic group obtained by linking a plurality of aromatic rings of the aromatic hydrocarbon group or the aromatic heterocyclic group,
R1, R2, and R3 each independently represent deuterium, a halogen, a cyano group, a nitro group, an alkyl group having 1 to 20 carbon atoms, an aralkyl group having 7 to 38 carbon atoms, an alkenyl group having 2 to 20 carbon atoms, an alkynyl group having 2 to 20 carbon atoms, a dialkylamino group having 2 to 40 carbon atoms, a diarylamino group having 12 to 44 carbon atoms, a diaralkylamino group having 14 to 76 carbon atoms, an acyl group having 2 to 20 carbon atoms, an acyloxy group having 2 to 20 carbon atoms, an alkoxy group having 1 to 20 carbon atoms, an alkoxycarbonyl group having 2 to 20 carbon atoms, an alkoxycarbonyloxy group having 2 to 20 carbon atoms, an alkylsulfonyl group having 1 to 20 carbon atoms, a substituted or unsubstituted aromatic hydrocarbon group having 6 to 24 carbon atoms, a substituted or unsubstituted aromatic heterocyclic group having 3 to 18 carbon atoms, or a linked aromatic group obtained by linking a plurality of aromatic rings of the aromatic hydrocarbon group or the aromatic heterocyclic group, and when any one of the groups has a hydrogen atom, the hydrogen atom may be substituted with deuterium or a halogen, and
“b”, “c”, and “p” each represent a substitution number, “b”s each independently represent an integer of from 0 to 4, “c” represents an integer of from 0 to 2, and “p” represents an integer of from 0 to 3.

11. The polymer for an organic electroluminescent device according to claim 10, wherein the polymer includes a structural unit represented by the following general formula (2): 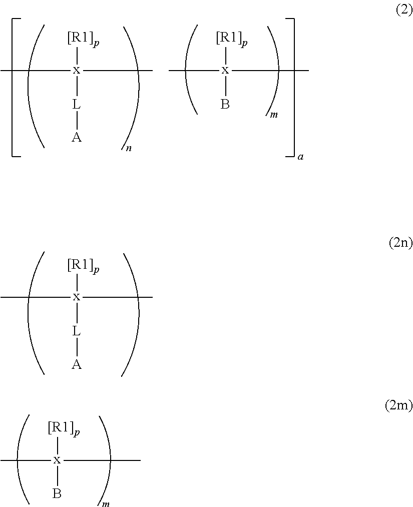
wherein the structural unit represented by the general formula (2) includes a structural unit represented by the formula (2n) and a structural unit represented by the formula (2m), the structural units each represented by the formula (2n) may be the same or different from repeating unit to repeating unit, and the structural units each represented by the formula (2m) may also be the same or different from repeating unit to repeating unit,
in the general formula (2), the formula (2n), and the formula (2m),
“x”, A, L, R1, and “p” are identical in meaning to those of the general formula (1),
B represents a hydrogen atom, a substituted or unsubstituted aromatic hydrocarbon group having 6 to 24 carbon atoms, a substituted or unsubstituted aromatic heterocyclic group having 3 to 17 carbon atoms, or a linked aromatic group obtained by linking a plurality of aromatic rings of the aromatic hydrocarbon group or the aromatic heterocyclic group,
“n” and “m” each represent an abundance molar ratio, and fall within ranges of 0.5≤n≤1 and 0≤m≤0.5, and
“a” represents an average number of the repeating units, and represents a number of from 2 to 1,000.

12. The polymer for an organic electroluminescent device according to claim 10, wherein the polyphenylene structure of the main chain is linked at a meta position or an ortho position.

13. The polymer for an organic electroluminescent device according to claim 10, wherein the polymer has a solubility in toluene at 40° C. of 0.5 wt % or more.

14. The polymer for an organic electroluminescent device according to claim 10, wherein the polymer has a reactive group at a terminal, or in a side chain, of the polyphenylene structure, and is insolubilized through application of energy, such as heat or light.

15. A composition for an organic electroluminescent device, comprising the polymer for an organic electroluminescent device of claim 10, which is dissolved or dispersed, alone or as a mixture with another material, in a solvent.

16. A method of producing an organic electroluminescent device, comprising applying the composition for an organic electroluminescent device of claim 15 to form the composition into an organic layer.

17. An organic electroluminescent device, comprising an organic layer containing the polymer for an organic electroluminescent device of claim 10.

18. The organic electroluminescent device according to claim 17, wherein the organic layer is at least one layer selected from a light-emitting layer, a hole-injecting layer, a hole-transporting layer, an electron-transporting layer, an electron-injecting layer, a hole-blocking layer, an electron-blocking layer, an exciton-blocking layer, and a charge-generating layer.
